(19) United States
(12) Patent Application Publication
(10) Pub. No.: US 2014/0225179 A1
(43) Pub. Date: Aug. 14, 2014

(54) NONVOLATILE SEMICONDUCTOR MEMORY DEVICE

(71) Applicant: KABUSHIKI KAISHA TOSHIBA, Tokyo (JP)

(72) Inventor: Kenji AOYAMA, Yokohama-shi (JP)

(73) Assignee: KABUSHIKI KAISHA TOSHIBA, Tokyo (JP)

(21) Appl. No.: 13/831,490

(22) Filed: Mar. 14, 2013

Related U.S. Application Data
(60) Provisional application No. 61/763,286, filed on Feb. 11, 2013.

(51) Int. Cl. H01L 29/792; H01L 27/088

(52) U.S. Cl. CPC H01L 29/792; H01L 27/088
USPC 257/316

(57) ABSTRACT

According to one embodiment, a memory cell includes a gate insulating layer on the active area, a floating gate electrode on the gate insulating layer, the floating gate electrode having a lower portion with a first width and a higher portion with a second width narrower than the first width, an intermediate insulating layer covering an end of the higher portion of the floating gate electrode, a charge storage layer being adjacent to the intermediate layer, an inter-electrode insulating layer covering the floating gate electrode and the charge storage layer, and a control gate electrode on the inter-electrode insulating layer.

### CROSS-REFERENCE TO RELATED APPLICATIONS

This application claims the benefit of U.S. Provisional Application No. 61/763,286, filed Feb. 11, 2013, the entire contents of which are incorporated herein by reference.

### FIELD

Embodiments described herein relate generally to a nonvolatile semiconductor memory device.

### BACKGROUND

Cell structures advantageous for finer memory cells are under development for a nonvolatile semiconductor memory device such as a NAND flash memory. For example, flat cells reduce concave-convex of the memory cell by adopting a flat surface where a floating gate electrode and a control gate electrode are opposed to each other. Hybrid cells avoid the narrowing of a threshold window due to finer memory cells by adopting two charge storage layers (for example, a floating gate electrode and a charge trap layer).

### BRIEF DESCRIPTION OF THE DRAWINGS

FIG. 1 is a circuit diagram showing an example of a nonvolatile semiconductor memory device;

FIG. 2 is a plan view showing a first embodiment;

FIG. 3 is a sectional view along line in FIG. 2;

FIG. 4 is a sectional view along IV-IV line in FIG. 2;

FIG. 5 is a sectional view along V-V line in FIG. 2;

FIGS. 6 and 7 are sectional views showing a modification of the first embodiment;

FIGS. 8 to 12 are perspective views showing a method of manufacturing the device in FIGS. 2 to 5;

FIG. 13 is a plan view showing a second embodiment;

FIG. 14 is a sectional view along XIV-XIV line in FIG. 13;

FIG. 15 is a sectional view along XV-XV line in FIG. 13;

FIG. 16 is a sectional view along XVI-XVI line in FIG. 13;

FIGS. 17 and 18 are sectional views showing a modification of the second embodiment;

FIGS. 19 to 23 are perspective views showing the method of manufacturing the device in FIGS. 13 to 16;

FIG. 24 is a plan view showing a third embodiment;

FIG. 25 is a sectional view along XXV-XXV line in FIG. 24;

FIG. 26 is a sectional view along XXVI-XXVI line in FIG. 24;

FIG. 27 is a sectional view along XXVII-XXVII line in FIG. 24;

FIGS. 28 and 29 are sectional views showing a modification of the third embodiment;

FIGS. 30 to 34 are perspective views showing the method of manufacturing the device in FIGS. 24 to 27;

FIG. 35 is a plan view showing a peripheral transistor corresponding to the first embodiment;

FIG. 36 is a sectional view along XXXVI-XXXVI line in FIG. 35;

FIG. 37 is a sectional view along XXXVII-XXXVII line in FIG. 35;

FIG. 38 is a plan view showing the peripheral transistor corresponding to the second embodiment;

FIG. 39 is a plan view showing the peripheral transistor corresponding to the third embodiment;

FIG. 40 is a plan view showing a modification of the peripheral transistor;

FIG. 41 is a sectional view along XLI-XLI line in FIG. 40; and

FIG. 42 is a sectional view along XLII-XLII line in FIG. 40.

### DETAILED DESCRIPTION

In general, according to one embodiment, a nonvolatile semiconductor memory device comprises: a first active area which extends to a first direction, and which has an end in a second direction intersect with the first direction and a an upper surface in a third direction intersect with the first and second directions; an element isolation insulating layer which is adjacent to the end of the first active area, and which has an upper surface higher than the upper surface of the first active area; and a memory cell on the first active area. The memory cell comprises: a first gate insulating layer on the first active area; a first floating gate electrode on the first gate insulating layer; a first intermediate insulating layer covering a side face of the first floating gate electrode in the second direction; a first charge storage layer being faced to the side face of the first floating gate electrode via the first intermediate insulating layer; a first inter-electrode insulating layer covering the first floating gate electrode and the first charge storage layer; and a control gate electrode on the first inter-electrode insulating layer, the control gate electrode extending to the second direction.

### 1. BASIC CONCEPT

Flat cells realize finer memory cells and hybrid cells avoid the narrowing of the threshold window due to finer memory cells. However, flat cells and hybrid cells are not necessarily compatible with each other.

For a memory cell adopting both, for example, a charge trap layer is arranged on a floating gate electrode. In this case, the threshold window mainly depends on the amount of charge in the charge trap layer and thus, it is desirable to increase the amount of charge that can be trapped in the charge trap layer by increasing the volume of the charge trap layer. However, increasing the volume of the charge trap layer means increasing the thickness of the charge trap layer. An increased thickness of the charge trap layer leads to the fall of a coupling ratio of memory cells, which makes an efficient infusion of charges into the charge trap layer difficult.

When flat cells and hybrid cells are adopted, a select transistor connected to a memory cell in series or peripheral transistor arranged around a memory cell has the same structure as the memory cell, that is, a structure having a charge storage layer. In this case, unintended charges stored in the charge storage layers of these transistors could cause a malfunction.

Therefore, in the following embodiments, a new cell structure in which, instead of adopting a flat cell, a convex type (rocket type) floating gate electrode is adopted in a hybrid cell is proposed. The hybrid cell refers to a structure having a floating gate electrode and a charge trap layer.

The new cell structure is also applicable to structures other than the hybrid cell, for example, a structure (double floating cell) having two floating gate electrodes.

For example, the memory cell is arranged on an active area and has a convex type floating gate electrode. The floating gate electrode has a width narrower than that of the active area. The floating gate electrode may be a convex type having a continuously changing width or a fixed width or a convex type having a discontinuously changing width.

Being continuous means that the width changes at an approximately constant rate and being discontinuous means that the width changes abruptly at a rate clearly different from the approximately constant rate.

An intermediate insulating layer covers the side of a floating gate electrode and a charge storage layer is arranged abutting on the intermediate insulating layer. An inter-electrode insulating layer covers the floating gate electrode and the charge storage layer and a control gate electrode is arranged on the inter-electrode insulating layer.

A select transistor or a peripheral transistor is arranged on the active area and has a convex type floating gate electrode. The floating gate electrode has a width narrower than that of the active area. The floating gate electrode may be a convex type having a continuously changing width or a fixed width or a convex type having a discontinuously changing width.

An intermediate insulating layer covers the side of a floating gate electrode and a charge storage layer is arranged abutting on the intermediate insulating layer. An inter-electrode insulating layer covers the floating gate electrode and the charge storage layer and has an opening portion. A gate electrode (select gate electrode or logic gate electrode) is in contact with the floating gate electrode via the opening portion.

According to such a cell structure, first the opposing area of the floating gate electrode and the control gate electrode can be increased by adopting the convex type for the floating gate electrode. That is, the fall of the coupling ratio, which has been a challenge for the flat cell, can be prevented and therefore, the charge injection can be made more efficient and write characteristics can be improved.

Secondly, the charge storage layer, for example, the charge trap layer can be arranged on the side face (higher portion side face) of the floating gate electrode by adopting the convex type for the floating gate electrode. Therefore, the coupling ratio does not fall even if the volume of the charge trap layer is increased. That is, the threshold window can be broadened by increasing the amount of charge (volume of the charge trap layer) trapped inside the charge trap layer.

Thirdly, the charge trap layer can be arranged on the side face of the floating gate electrode and thus, for example, an opening portion can be provided in the inter-electrode insulating layer in a select transistor or peripheral transistor to expose an upper surface of the convex type floating gate electrode. That is, these transistors have a structure different from that of a memory cell, that is, a structure in which the floating gate electrode and the control gate electrode are short-circuited. Therefore, malfunctions of these transistors can be prevented.

### 2. EMBODIMENTS

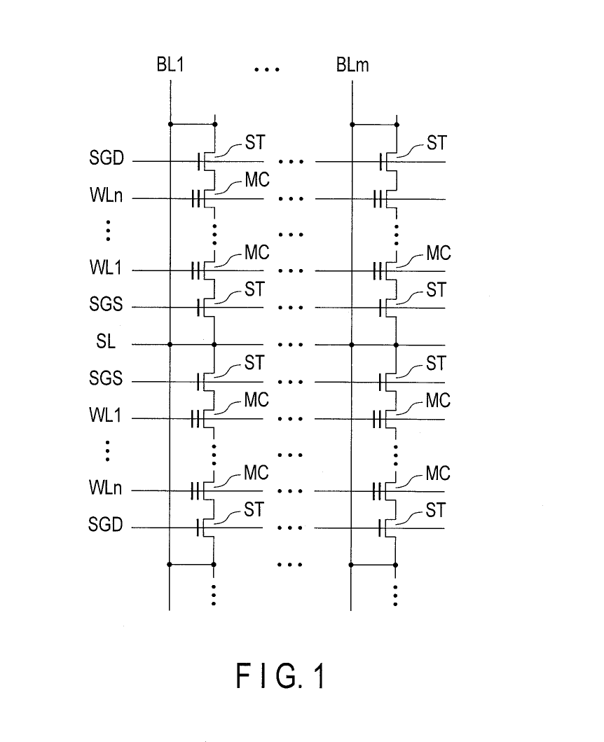

The above memory cell structure is applicable to nonvolatile semiconductor memory devices capable of adopting hybrid cells or double floating cells. For example, the NAND flash memory shown in FIG. 1 can adopt the above memory cell structure.

In FIG. 1, a NAND string is connected between a source line SL and bit lines BL1, . . . BLm. The NAND string includes a plurality of memory cells MC connected in series and two select transistors ST connected to both ends thereof. The plurality of memory cells MC is each connected to a plurality of word lines (control gate electrodes) WL1, . . . WLn and the two select transistors ST are each connected to two select gate lines SGS, SGD.

In the following embodiments, the structure of the memory cell MC and the select transistor ST of a NAND flash memory as shown, for example, in FIG. 1 will be described.

### (1) First Embodiment

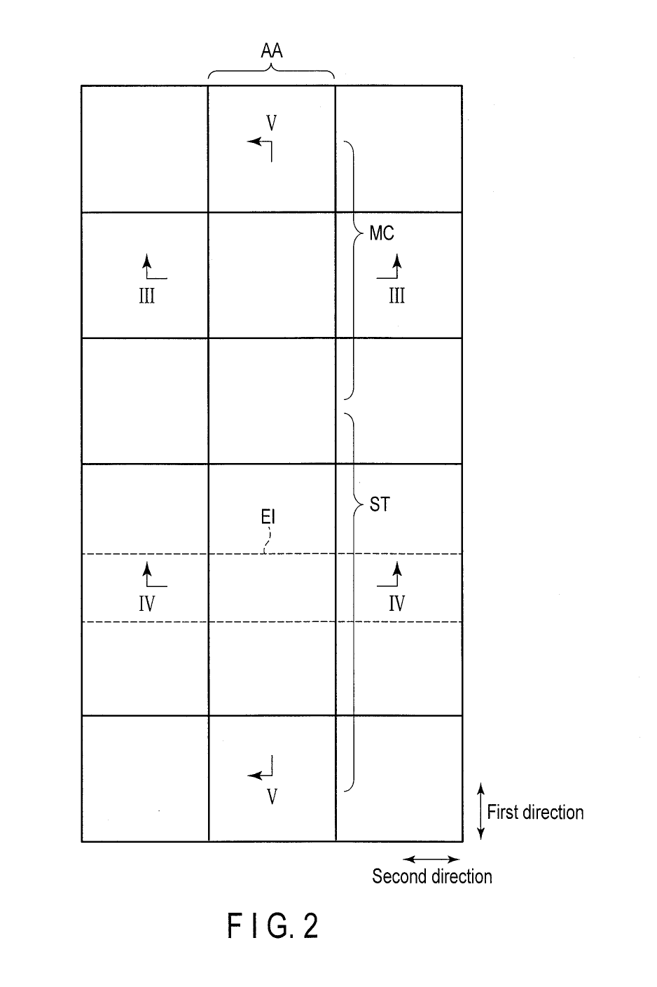

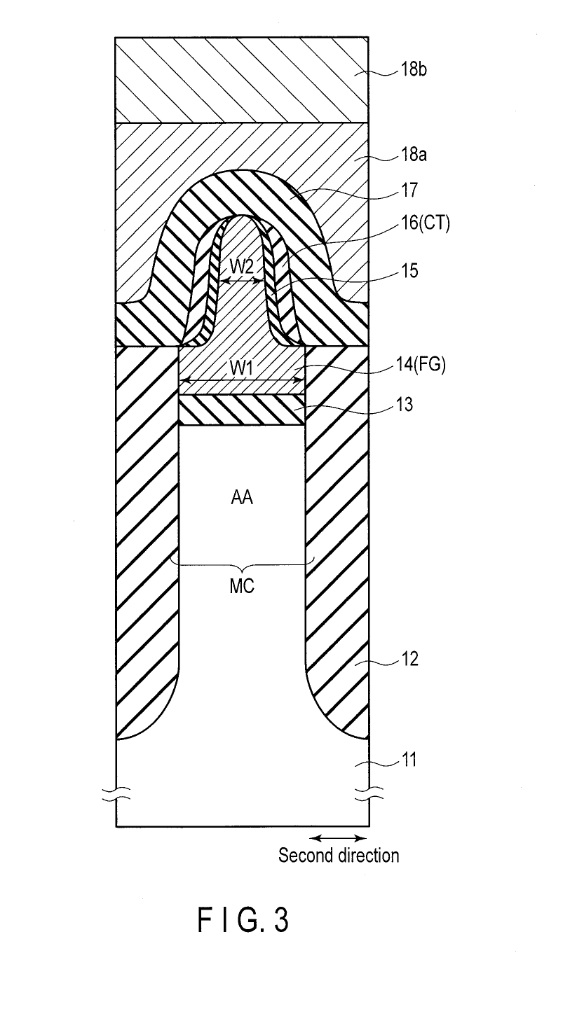

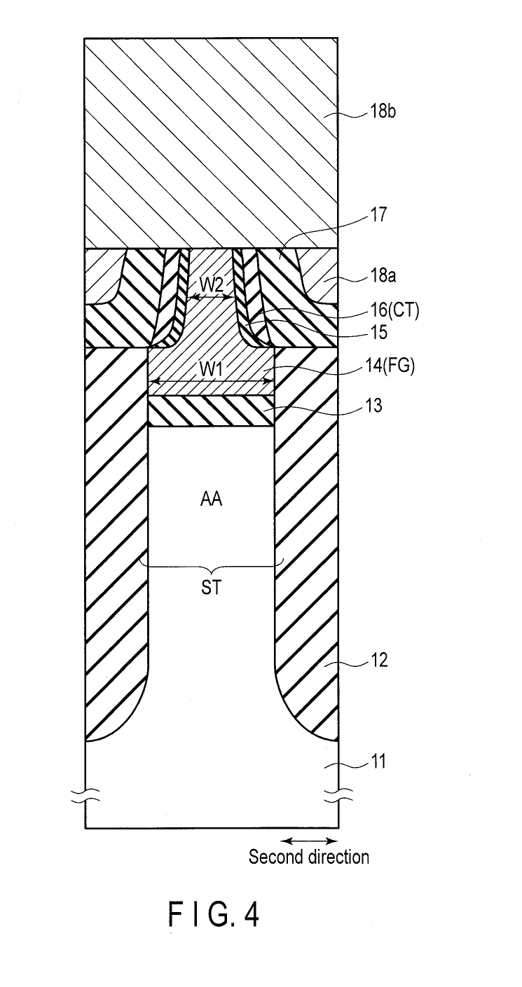

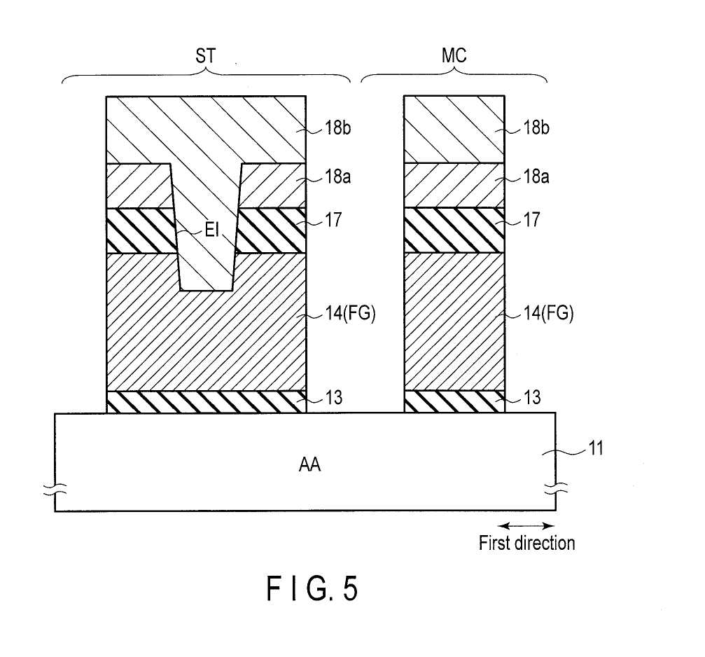

FIG. 2 shows a nonvolatile semiconductor memory device. FIG. 3 is a sectional view along line in FIG. 2, FIG. 4 is a sectional view along IV-IV line in FIG. 2, and FIG. 5 is a sectional view along V-V line in FIG. 2.

An active area AA as a semiconductor substrate 11 extends in a first direction, has an end in a second direction intersecting with the first direction, and has an upper surface in a third direction intersecting with the first and second directions. An element isolation insulating layer 12 has an STI (Shallow Trench Isolation) structure and is embedded in the semiconductor substrate 11. The element isolation insulating layer 12 is adjacent to the end of the active area AA and has an upper surface higher than the upper surface of the active area.

The memory cell MC and the select transistor ST are arranged on the active area AA and mutually connected in series.

The structure of the memory cell MC is as described below.

A gate insulating layer 13 is arranged on the active area AA. A floating gate electrode 14 (FG) is arranged on the gate insulating layer 13. The floating gate electrode 14 (FG) includes a conductive layer in an electrically floating state.

The floating gate electrode 14 (FG) has a lower portion having a first width W1 in the second direction and a higher portion having a second width W2 narrower than the first width W1 in the second direction.

For example, the lower portion is a portion of the floating gate electrode 14 (FG) positioned lower than the upper surface of the element isolation insulating layer 12 and the higher portion is a portion of the floating gate electrode 14 (FG) positioned higher than the upper surface of the element isolation insulating layer 12.

The end in the second direction of the lower portion of the floating gate electrode 14 (FG) is in contact with the element isolation insulating layer 12. That is, for example, the first width, W1 of the lower portion of the floating gate electrode 14 (FG) is equal to the width of the active area AA in the second direction.

The second width W2 of the higher portion of the floating gate electrode 14 (FG) decreases with an increasing distance (increasing height) from the semiconductor substrate 11. The side face of the floating gate electrode 14 (FG) in the second direction is a curved surface.

An intermediate insulating layer 15 covers the end (side face) in the second direction of the higher portion of the floating gate electrode 14 (FG).

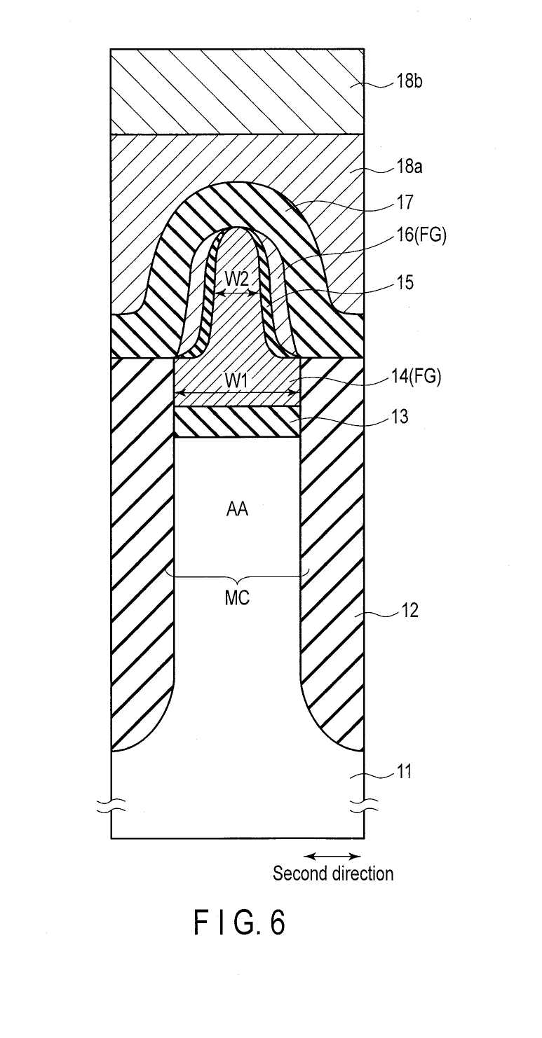

A charge storage layer 16 (CT) is adjacent to the intermediate insulating layer 15. The charge storage layer 16 (CT) is, for example, a charge trap layer (insulating layer having a charge trap level). Instead, however, as shown in FIG. 6, a floating gate electrode (conductive layer in an electrically floating state) may be used as the charge storage layer 16 (FG) (double floating cell).

An inter-electrode insulating layer 17 covers the floating gate electrode 14 (FG) and the charge storage layer 16 (CT). Conductive layers (control gate electrodes) 18a, 18b are arranged on the inter-electrode insulating layer 17 and extend in the second direction.

In the present example, the conductive layers 18a, 18b as control gate electrodes have a two-layer structure, but are not limited to such a structure.

The floating gate electrode 14 (FG) has the discontinuous first width W1 (lower portion) and second width W2 (higher portion), but the floating gate electrode 14 (FG) may have a continuously changing width or a constant width instead.

The structure of the select transistor ST is as described below.

The gate insulating layer 13 is arranged on the active area AA. The floating gate electrode 14 (FG) is arranged on the gate insulating layer 13. In contrast to the memory cell MC, the floating gate electrode 14 (FG) is electrically short-circuited to the conductive layers 18a, 18b as control gate electrodes.

The floating gate electrode 14 (FG) has a lower portion having the first width W1 in the second direction and a higher portion having the second width W2 narrower than the first width W1 in the second direction.

Also in the select transistor ST, for example, the lower portion is a portion of the floating gate electrode 14 (FG) positioned lower than the upper surface of the element isolation insulating layer 12 and the higher portion is a portion of the floating gate electrode 14 (FG) positioned higher than the upper surface of the element isolation insulating layer 12.

The end in the second direction of the lower portion of the floating gate electrode 14 (FG) is in contact with the element isolation insulating layer 12. That is, for example, the first width W1 of the lower portion of the floating gate electrode 14 (FG) is equal to the width of the active area AA in the second direction.

The second width W2 of the higher portion of the floating gate electrode 14 (FG) decreases with an increasing distance (increasing height) from the semiconductor substrate 11. The side face of the floating gate electrode 14 (FG) in the second direction is a curved surface.

The intermediate insulating layer 15 covers the end (side face) in the second direction of the higher portion of the floating gate electrode 14 (FG).

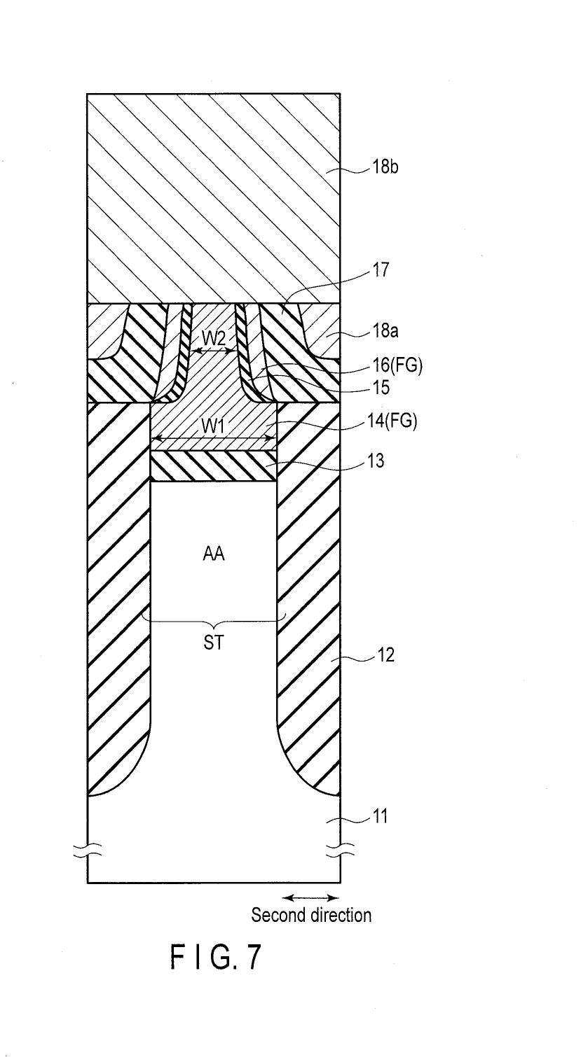

The charge storage layer 16 (CT) is adjacent to the intermediate insulating layer 15. The charge storage layer 16 (CT) is, for example, a charge trap layer (insulating layer). Instead, however, as shown in FIG. 7, a floating gate electrode (conductive layer) may be used as the charge storage layer 16 (FG).

The inter-electrode insulating layer 17 covers the floating gate electrode 14 (FG) and the charge storage layer 16 (CT) and has an opening portion EI. Conductive layers (select gate electrodes) 18a, 18b are arranged on the inter-electrode insulating layer 17 and extend in the second direction. The conductive layer 18a, 18b are electrically connected to the floating gate electrode 14 (FG) via the opening portion EI of the inter-electrode insulating layer 17.

In the present example, the conductive layers 18a, 18b as select gate electrodes have a two-layer structure, but are not limited to such a structure.

The floating gate electrode 14 (FG) has the discontinuous first width W1 (lower portion) and second width W2 (higher portion), but the floating gate electrode 14 (FG) may have a continuously changing width or a constant width instead.

Further, in the present example, sources/drains (impurity area) of the memory cell MC and the select transistor ST are omitted. This takes into consideration the fact that when the memory cell MC becomes increasingly finer, a conductive path is formed by the so-called fringe effect even if sources/drains are not present. However, sources/drains of the memory cell MC and the select transistor ST may be added.

Examples of materials will be described below.

In the structure of FIGS. 2 to 7, the semiconductor substrate 11 is, for example, a silicon substrate and the element isolation insulating layer 12 and the gate insulating layer 13 are, for example, silicon oxide layers.

The floating gate electrode 14 (FG) includes, for example, a metal layer, a conductive polysilicon layer, a metal compound layer, and a laminated layer of these layers.

The metal layer is, for example, a titanium layer, a tungsten layer, a tantalum layer, a nickel layer or the like and the metal compound layer is a titanium nitride layer, a tungsten nitride layer, a tantalum nitride layer, a nickel nitride layer, a titanium silicide layer, a tungsten silicide layer, a tantalum silicide layer, a nickel silicide layer or the like.

The intermediate insulating layer 15 is, for example, a silicon oxide layer having a thickness of 10 nm or less.

The intermediate insulating layer 15 may include a high dielectric constant material having a dielectric constant higher than the dielectric constant of the silicon oxide layer. The high dielectric constant material is, for example, metallic oxide such as Al₂O₃, ZrO₂, HfO₂, HfSiO, HfAlO, LaAlO(LAO), LaAlSiO(LASO) or a laminated structure of these metallic oxides. The high dielectric constant material may also be a laminated structure of a silicon oxide layer and a silicon nitride layer such as ONO.

The charge storage layer 16 (CT) is an insulating layer having a charge trap level such as SiN, SiON, Al₂O₃, and HfO.

The inter-electrode insulating layer 17 includes, for example, a high dielectric constant material. The high dielectric constant material is, for example, metallic oxide such as Al₂O₃, ZrO₂, HfO₂, HfSiO, HfAlO, LaAlO(LAO), LaAlSiO(LASO) or a laminated structure of these metallic oxides. The high dielectric constant material may also be a laminated structure of a silicon oxide layer and a silicon nitride layer such as ONO.

The conductive layer 18a as a control gate electrode or a select gate electrode is, for example, a conductive polysilicon layer. The conductive layer 18b as a control gate electrode or a select gate electrode is, for example, a metal layer or a metal silicide layer.

Examples of the metal layer include a titanium layer, a tungsten layer, a tantalum layer, a nickel layer or the like and examples of the metal silicide layer include a titanium silicide layer, a tungsten silicide layer, a tantalum silicide layer, a nickel silicide layer or the like.

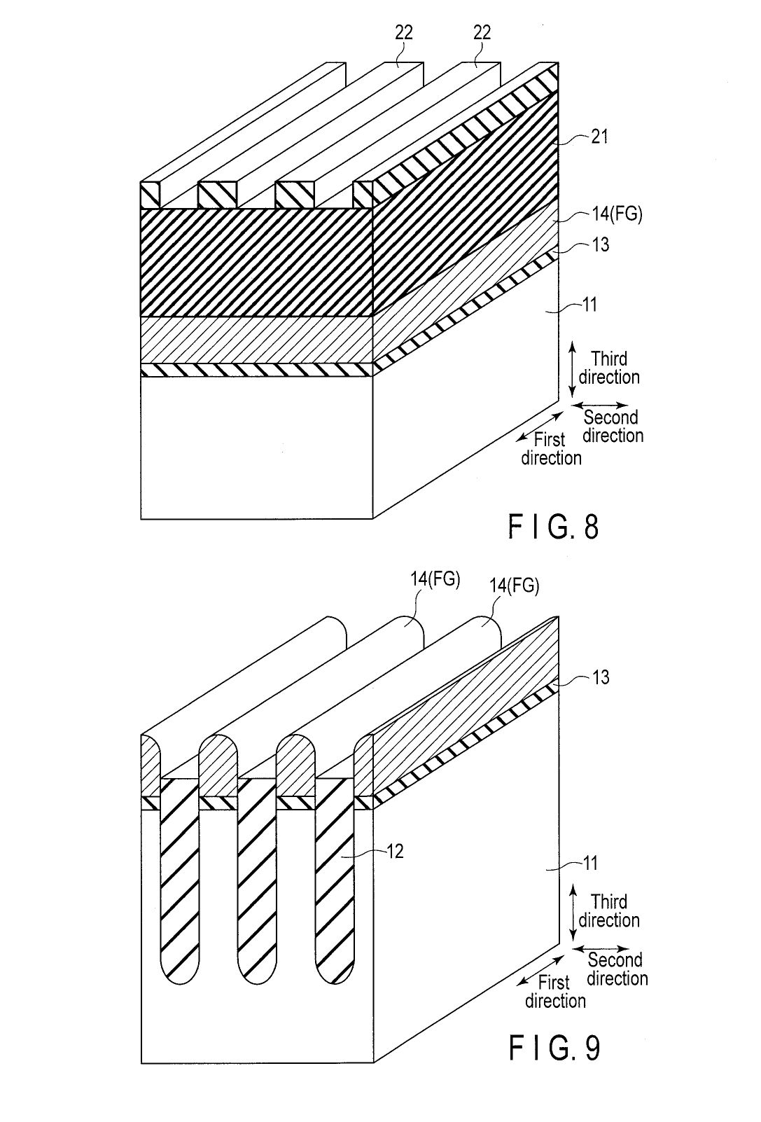

The method of manufacturing the device in FIGS. 2 to 5 is shown in FIGS. 8 to 12.

First, as shown in FIG. 8, the gate insulating layer (tunnel insulating layer) 13 is formed on the semiconductor substrate 11 and the floating gate electrode (conductive layer) 14 (FG) is formed on the gate insulating layer 13. A hard mask layer (for example, a silicon oxide layer, a silicon nitride layer and so on) 21 is formed on the floating gate electrode (conductive layer) 14 (FG). A resist layer 22 in a line & space pattern is formed on the hard mask 21 by PEP (Photo Engraving Process).

The hard mask layer 21 is etched by RIE using the resist layer 22 as a mask. Then, the resist layer 22 is removed.

Next, the floating gate electrode 14 (FG), the gate insulating layer 13, and the semiconductor substrate 11 are etched by RIE using the hard mask layer 21 as a mask.

As a result, as shown in FIG. 9, the floating gate electrode 14 (FG) is patterned to a line & space pattern. The upper surface of the floating gate electrode 14 (FG) becomes a curved surface. Further, in a space of the line & space pattern, a trench extending in the first direction is formed inside the semiconductor substrate 11.

The hard mask layer 21 in FIG. 8 is also removed by the etching process. After the etching process, however, the hard mask layer 21 in FIG. 8 may remain on the floating gate electrode 14 (FG).

Then, the element isolation insulating layer 12 filling the trench of the semiconductor substrate 11 is formed. Also, the element isolation insulating layer 12 is etched back to cause the element isolation insulating layer 12 to remain only in the trench inside the space of the line & space pattern.

The upper surface of the element isolation insulating layer 12 needs to be higher than the upper surface of the semiconductor substrate 11 or higher than the lower surface of the floating gate electrode 14 (FG). This is intended to prevent the semiconductor substrate 11 from being etched in a slimming process of the floating gate electrode 14 (FG) described later.

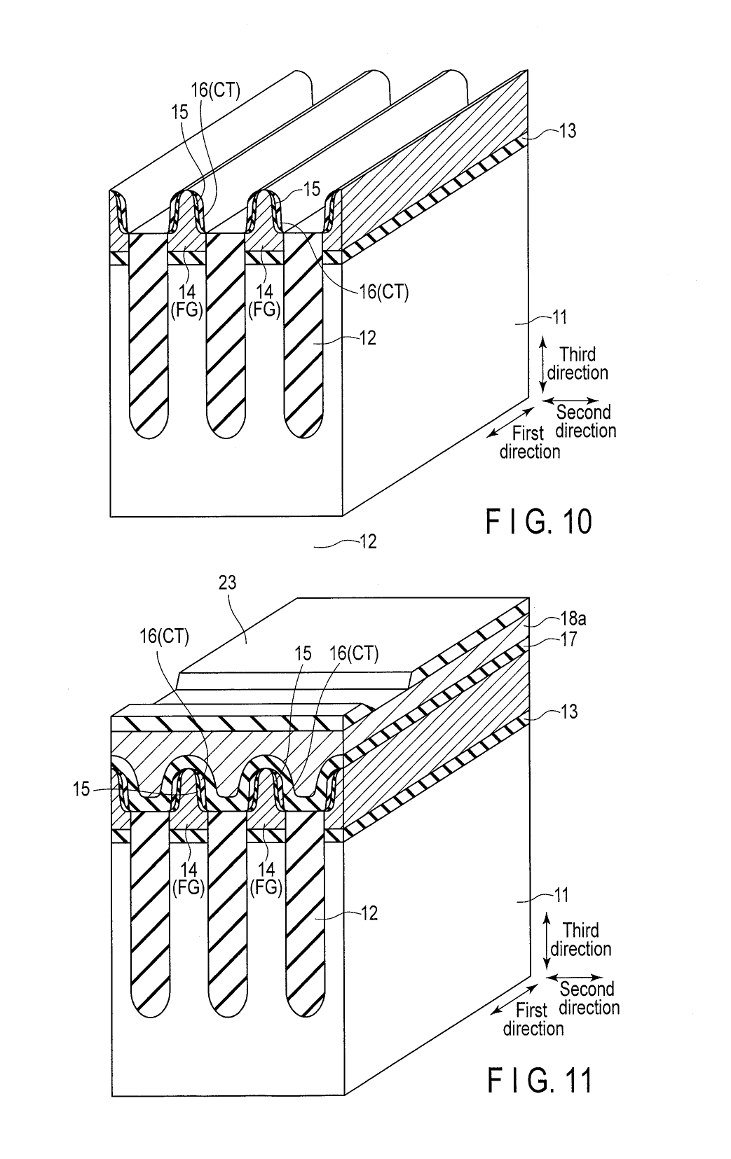

Next, as shown in FIG. 10, the width of the floating gate electrode 14 (FG) is made narrower than that of the active layer AA in the second direction by slimming the floating gate electrode 14 (FG).

If the upper surface of the element isolation insulating layer 12 is as high as or lower than the lower surface of the floating gate electrode 14 (FG), the width of the floating gate electrode 14 (FG) in the second direction becomes a continuously changing width or a constant width.

If, as shown in FIG. 10, the upper surface of the element isolation insulating layer 12 is higher than the lower surface of the floating gate electrode 14 (FG), by contrast, the width of the floating gate electrode 14 (FG) in the second direction becomes discontinuous between the lower portion and the higher portion.

Then, the intermediate insulating layer 15 covering the floating gate electrode 14 (FG) is formed and the charge storage layer 16 (CT) adjacent to the intermediate insulating layer 15 is formed. The intermediate insulating layer 15 and the charge storage layer 16 (CT) are caused to remain self-aligningly on the side face (end in the second direction) of the floating gate electrode 14 (FG) by etching the intermediate insulating layer 15 and the charge storage layer 16 (CT) by RIE.

That is, the intermediate insulating layer 15 and the charge storage layer 16 (CT) are self-aligningly formed in a hollow on the side face of the floating gate electrode 14 (FG) by slimming.

Next, as shown in FIG. 11, the inter-electrode insulating layer 17 covering the floating gate electrode 14 (FG) and the charge storage layer 16 (CT) is formed. Subsequently, the conductive layer 18a as a control gate electrode is formed on the inter-electrode insulating layer 17. Also, a resist layer 23 is formed on the conductive layer 18a by PEP.

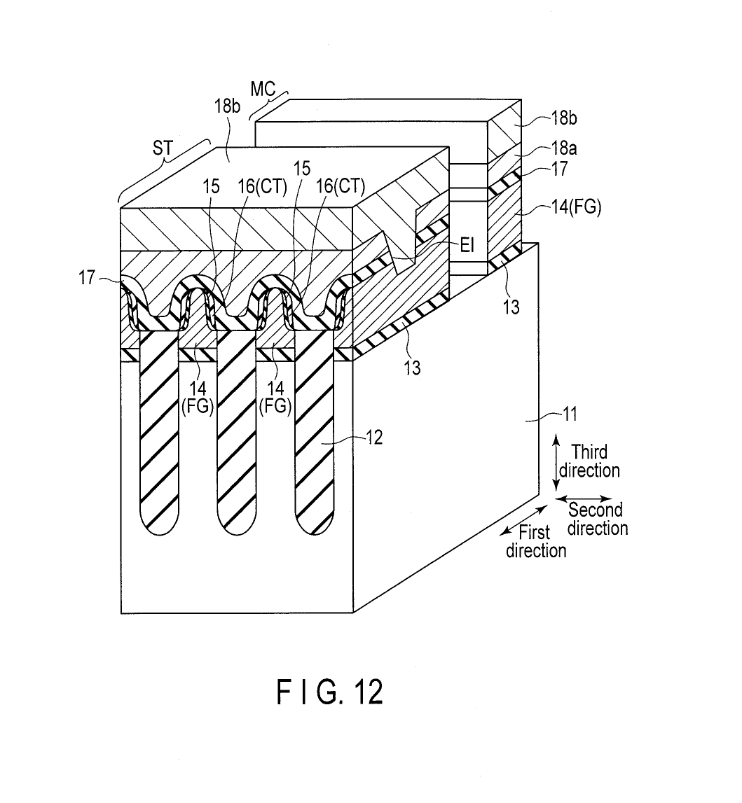

The conductive layer 18a and the inter-electrode insulating layer 17 are etched by RIE using the resist layer 23 as a mask. As a result, as shown in FIG. 12, the opening portion EI is formed in the inter-electrode insulating layer 17 in an area where the select transistor ST is formed. No opening portion is formed in the inter-electrode insulating layer 17 in an area where the memory cell MC is formed. Then, the resist layer 23 is removed.

Next, as shown in FIG. 12, the conductive layer 18b is formed on the conductive layer 18a. Also, a resist layer in a line & space pattern is formed on the conductive layer 18b by PEP. Then, the conductive layers 18a, 18b, the inter-electrode insulating layer 17, the floating gate electrode 14 (FG), and the gate insulating layer 13 are each etched by RIE using the resist layer as a mask.

As a result, the conductive layers 18a, 18b as control gate electrodes extending in the second direction are formed in an area where the memory cell MC is formed and the conductive layers 18a, 18b as select gate electrodes extending in the second direction are formed in an area where the select transistor ST is formed.

In an area where the select transistor ST is formed, the conductive layers 18a, 18b as select gate electrodes extending in the second direction are in contact with the floating gate electrode 14 (FG) via the opening portion provided in the inter-electrode insulating layer 17.

Then, the space between the memory cell MC and the select transistor ST is filled with an interlayer insulating layer (for example, a silicon oxide layer). However, the space between the memory cell MC and the select transistor ST may be made an air gap.

According to the first embodiment, as described above, the charge storage layers 16 (CT), 16 (FG) can be arranged on the side face of the floating gate electrode 14 (FG) by adopting the convex type floating gate electrode 14 (FG) in the memory cell MC (hybrid cell or double floating cell) to improve the coupling ratio or improve write characteristics by expanding the threshold window.

In the select transistor ST, a structure in which the floating gate electrode 14 (FG) and the conductive layers 18a, 18b as select gate electrodes are short-circuited can be realized by providing an opening portion in the inter-electrode insulating layer 17 and therefore, reliability of a nonvolatile semiconductor memory device can be improved by preventing a malfunction of the select transistor ST.

A structure similar to the structure of the select transistor ST can be adopted for a peripheral transistor formed around a memory cell array area and an adopted structure will be described together as an example of the peripheral transistor after all the embodiments are described.

### (2) Second Embodiment

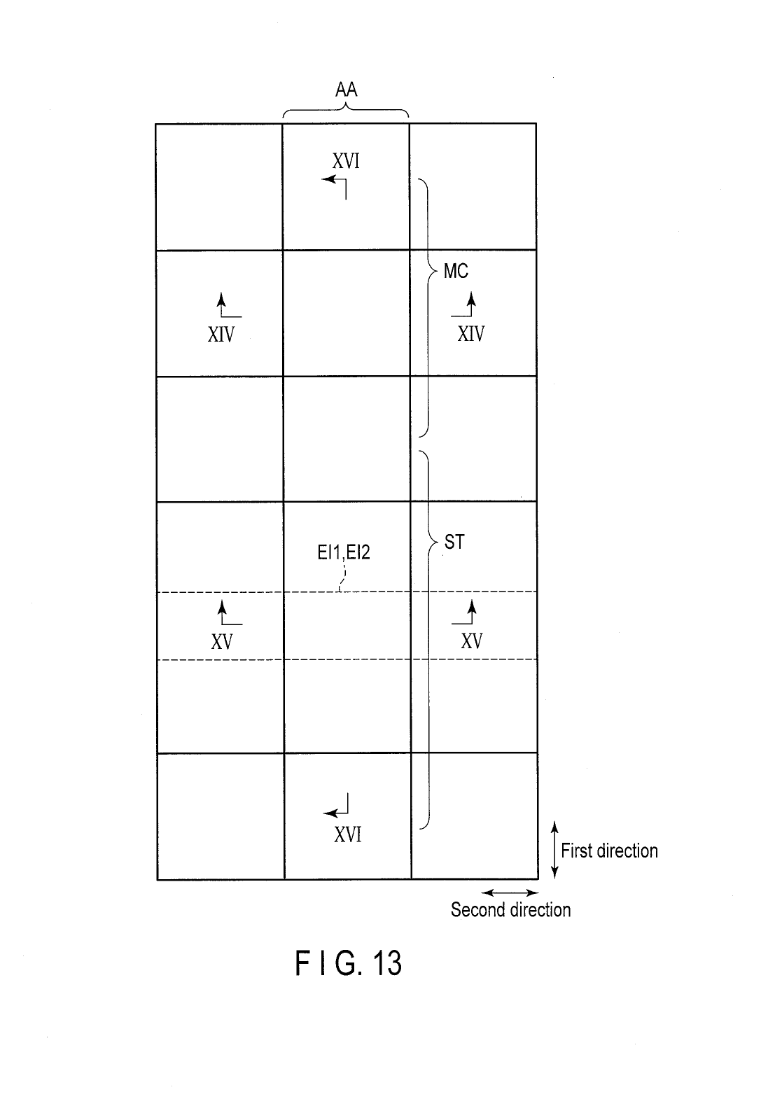

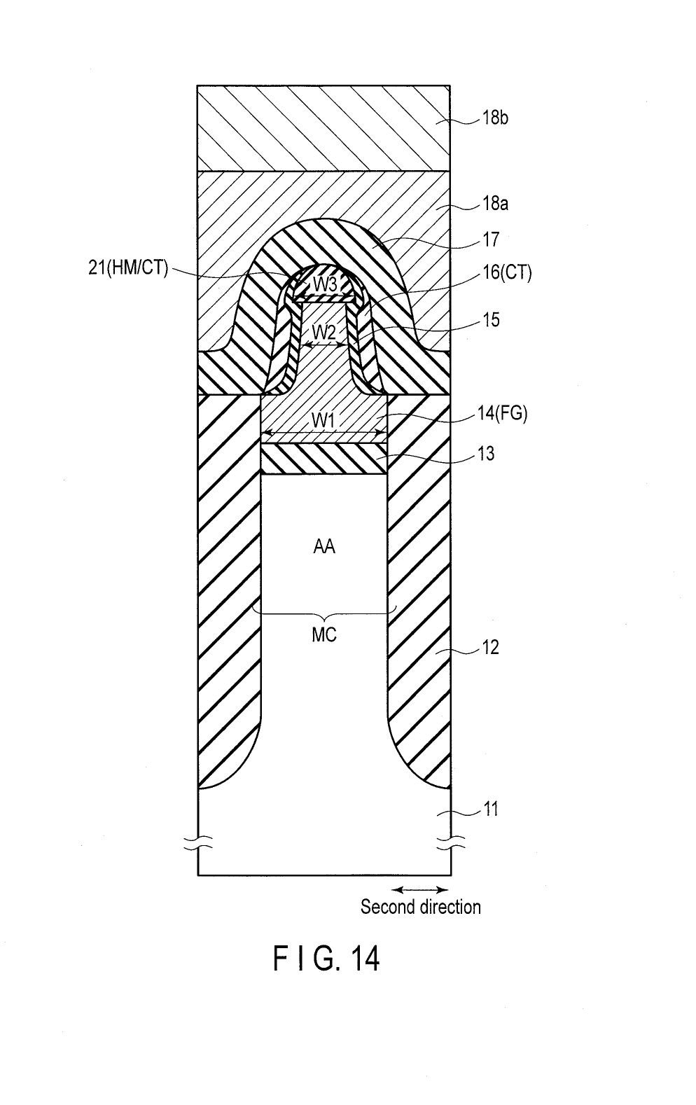

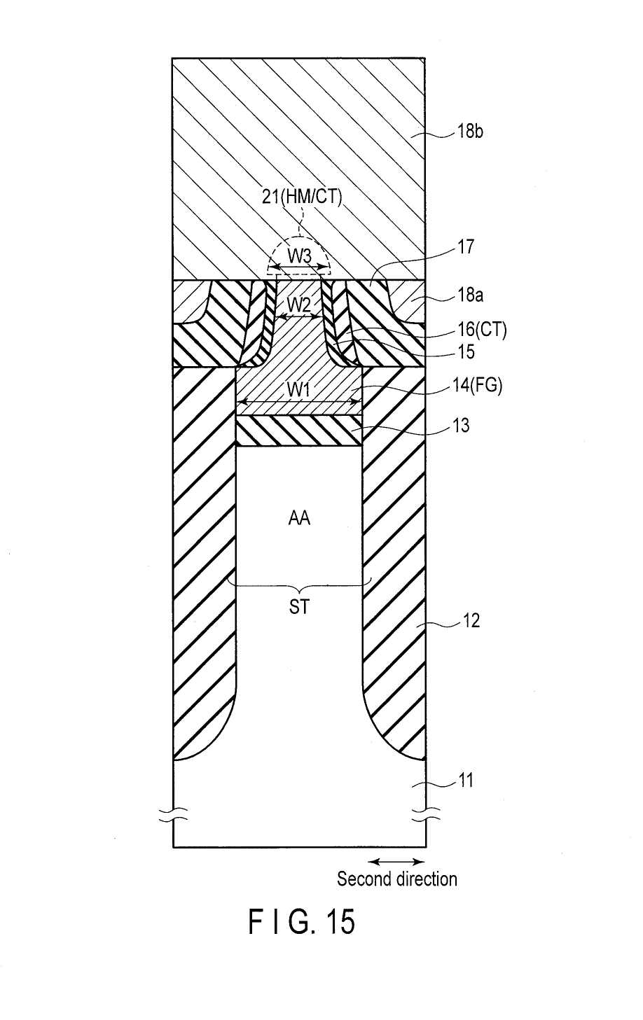

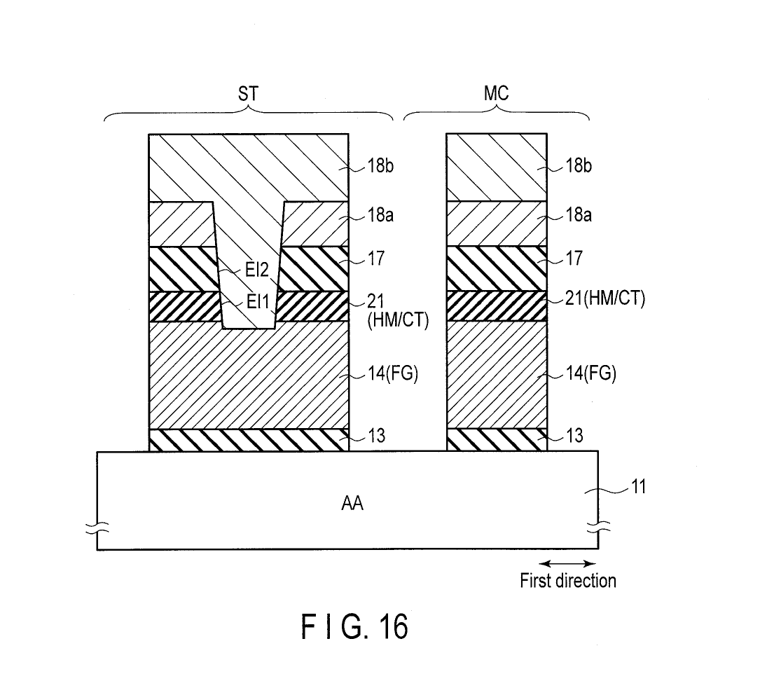

FIG. 13 shows a nonvolatile semiconductor memory device. FIG. 14 is a sectional view along XIV-XIV line in FIG. 13, FIG. 15 is a sectional view along XV-XV line in FIG. 13, and FIG. 16 is a sectional view along XVI-XVI line in FIG. 13.

The second embodiment is a modification of the first embodiment.

Thus, only differences from the first embodiment will be described below and a detailed description thereof is omitted by attaching the same reference numerals to the same elements as those described in the first embodiment.

Features of the structure of a memory cell MC are as described below.

A hard mask layer 21 (HM/CT) covers the upper surface of a floating gate electrode 14 (FG). The hard mask layer 21 has a third width W3 wider than a second width W2 of a higher portion of the floating gate electrode 14 (FG) in the second direction.

The hard mask layer 21 (HM/CT) is an inter-electrode insulating layer and has, for example, a function to block a leak current while writing/erasing. Instead, the hard mask layer 21 (HM/CT) may be caused to function as, for example, a charge trap layer. In this case, the hard mask layer 21 (HM/CT) is an insulating layer having a charge trap level.

An intermediate insulating layer 15 covers the end (side face) in the second direction of the higher portion of the floating gate electrode 14 (FG) and the end (side face) in the second direction of the hard mask layer 21 (HM/CT).

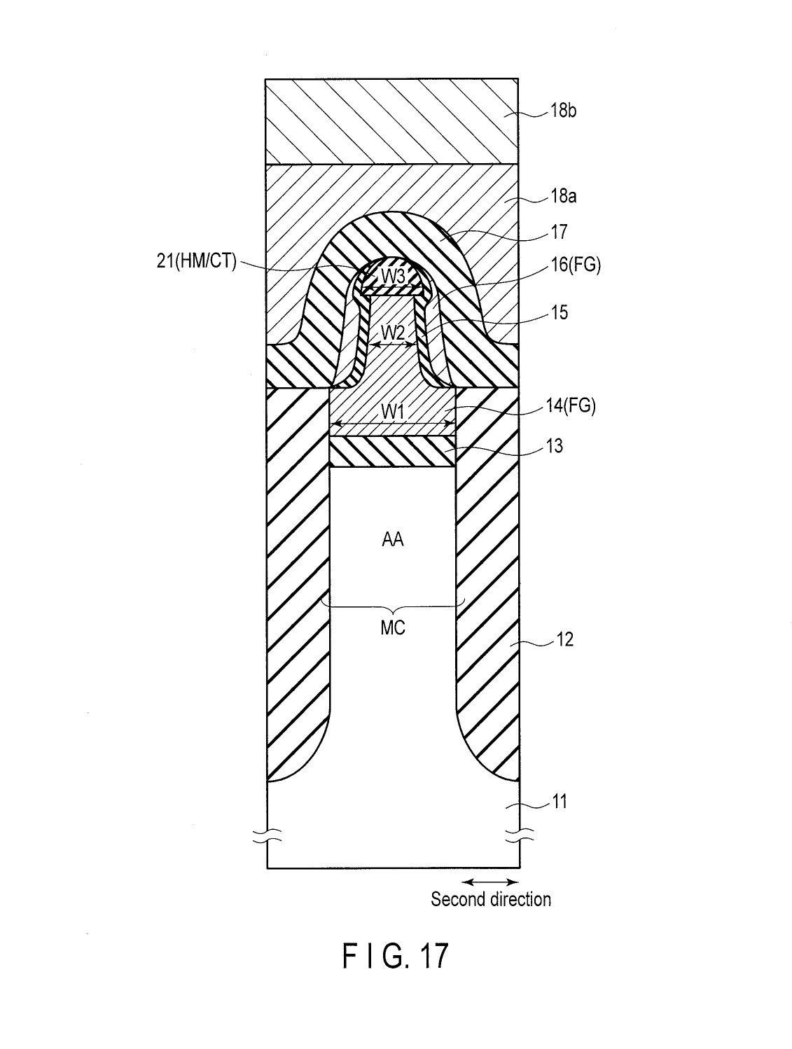

A charge storage layer 16 (CT) is adjacent to the intermediate insulating layer 15. The charge storage layer 16 (CT) is, for example, a charge trap layer (insulating layer having a charge trap level). Instead, however, as shown in FIG. 17, a floating gate electrode (conductive layer in an electrically floating state) may be used as the charge storage layer 16 (FG) (double floating cell).

When the hard mask layer 21 (HM/CT) is used as an inter-electrode insulating layer to block a leak current, it is desirable to, for example, make an electronic barrier (potential barrier to electrons) of the hard mask layer 21 (HM/CT) higher than that of the intermediate insulating layer 15. This is intended to prevent a leak current in an upper portion (particularly an edge portion) of the floating gate electrode 14 (FG) where electric fields are more likely to be concentrated while writing/erasing.

Materials satisfying conditions for the electronic barrier include alumina for the hard mask layer 21 (HM/CT) and silicon nitride for the intermediate insulating layer 15.

When the hard mask layer 21 (HM/CT) and the charge storage layer 16 (CT) are both used as charge trap layers, it is desirable to make the charge trap level of the hard mask layer 21 (HM/CT) lower than that of the charge storage layer 16 (CT). This is intended to particularly improve retention characteristics of the hard mask layer 21 (HM/CT).

For example, the concentration of electric fields in the upper portion (particularly an edge portion) of the floating gate electrode 14 (FG) caused while reading acts in a direction of a dropout of charges trapped in the hard mask layer 21 (HM/CT) therefrom. Such a dropout can be prevented by lowering the charge trap level of the hard mask layer 21 (HM/CT) because charges are thereby trapped by the hard mask layer 21 (HM/CT) more firmly.

Materials satisfying conditions for the charge trap level include alumina and hafnium oxide for the hard mask layer 21 (HM/CT) and silicon nitride for the charge storage layer 16 (CT).

Features of the structure of a select transistor ST are as described below.

The hard mask layer 21 (HM/CT) covers the upper surface of the floating gate electrode 14 (FG). The hard mask layer 21 has the third width W3 wider than the second width W2 of the higher portion of the floating gate electrode 14 (FG) in the second direction. The hard mask layer 21 (HM/CT) also includes an opening portion EI1.

The intermediate insulating layer 15 covers the end (side face) in the second direction of the higher portion of the floating gate electrode 14 (FG) and the end (side face) in the second direction of the hard mask layer 21 (HM/CT).

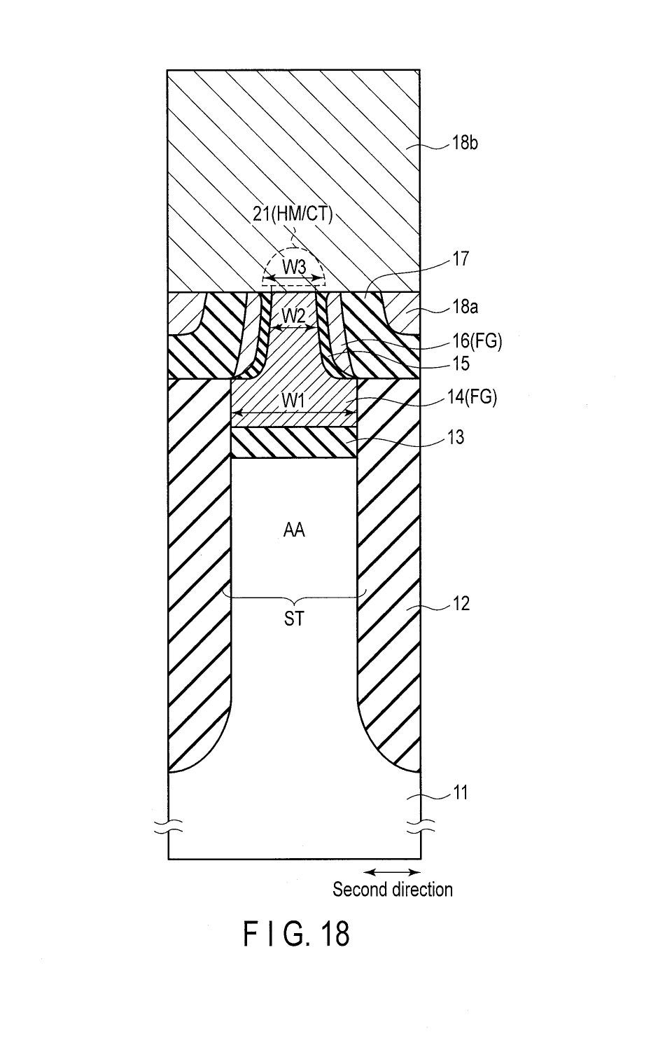

The charge storage layer 16 (CT) is adjacent to the intermediate insulating layer 15. The charge storage layer 16 (CT) is, for example, a charge trap layer (insulating layer). Instead, however, as shown in FIG. 18, a floating gate electrode (conductive layer) may be used as the charge storage layer 16 (FG).

The inter-electrode insulating layer 17 covers the floating gate electrode 14 (FG) and the charge storage layer 16 (CT) and has an opening portion EI2. Conductive layers (select gate electrodes) 18a, 18b are arranged on the inter-electrode insulating layer 17 and extend in the second direction. The conductive layer 18a, 18b are electrically connected to the floating gate electrode 14 (FG) via the opening portion EI1 of the hard mask layer 21 (HM/CT) and the opening portion EI2 of the inter-electrode insulating layer 17.

Examples of materials will be described below.

In the structure of FIGS. 13 to 18, the same materials as those described in the first embodiment can be used for a semiconductor substrate 11, an element isolation insulating layer 12, a gate insulating layer 13, the floating gate electrode 14 (FG), the intermediate insulating layer 15, the charge storage layer 16 (CT), the inter-electrode insulating layer 17, and the conductive layers 18a, 18b.

When the hard mask layer 21 (HM/CT) is used as an inter-electrode insulating layer, the hard mask layer 21 (HM/CT) includes, for example, a high dielectric constant material. The high dielectric constant material is, for example, metallic oxide such as Al₂O₃, ZrO₂, HfO₂, HfSiO, HfAlO, LaAlO(LAO), LaAlSiO(LASO) or a laminated structure of these metallic oxides. The high dielectric constant material may also be a laminated structure of a silicon oxide layer and a silicon nitride layer such as ONO.

When the hard mask layer 21 (HM/CT) is used as a charge trap layer, the hard mask layer 21 (HM/CT) is an insulating layer having a charge trap level such as SiN, SiON, Al₂O₃, and HfO.

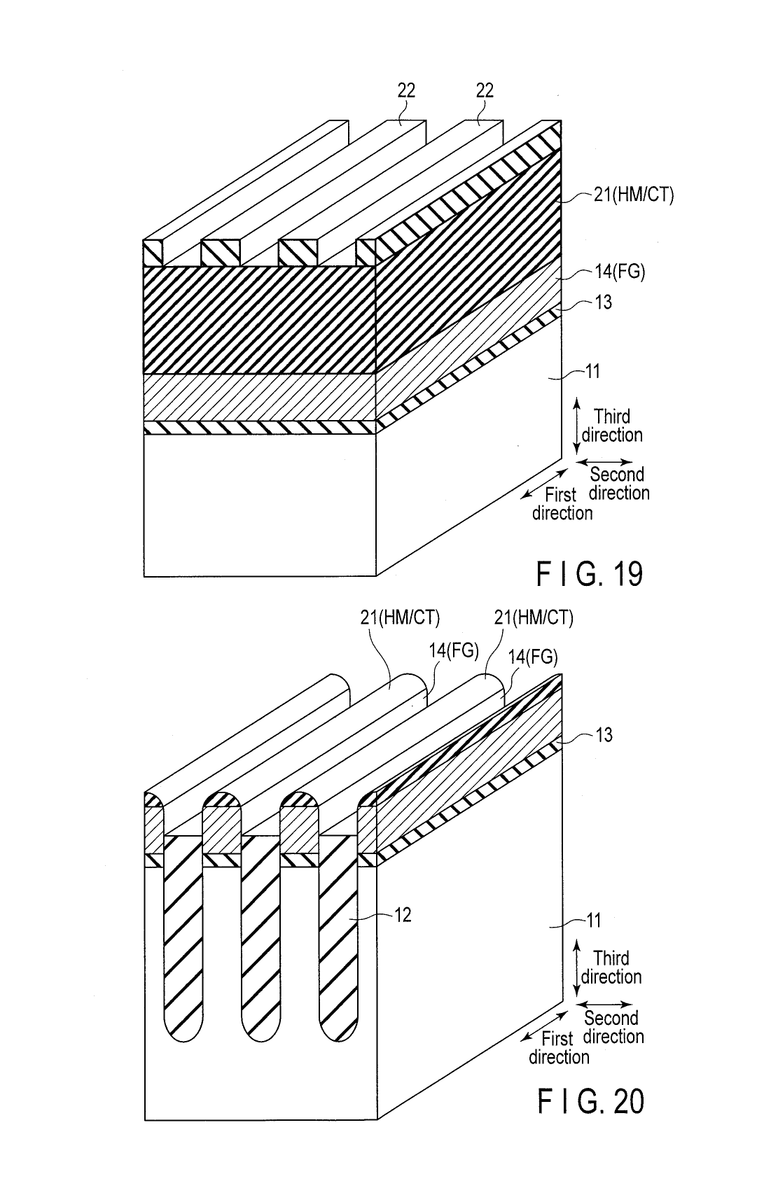

FIGS. 19 to 23 show the method of manufacturing the device in FIGS. 13 to 16.

First, as shown in FIG. 19, the gate insulating layer (tunnel insulating layer) 13 is formed on the semiconductor substrate 11 and the floating gate electrode (conductive layer) 14 (FG) is formed on the gate insulating layer 13. The hard mask layer (for example, a silicon oxide layer, a silicon nitride layer and so on) 21 is formed on the floating gate electrode (conductive layer) 14 (FG). A resist layer 22 in a line & space pattern is formed on the hard mask 21 by PEP (Photo Engraving Process).

The hard mask layer 21 is etched by RIE using the resist layer 22 as a mask. Then, the resist layer 22 is removed.

Next, the floating gate electrode 14 (FG), the gate insulating layer 13, and the semiconductor substrate 11 are etched by RIE using the hard mask layer 21 as a mask.

As a result, as shown in FIG. 20, the floating gate electrode 14 (FG) is patterned to a line & space pattern.

The hard mask layer 21 remains on the floating gate electrode 14 (FG). The upper surface of the hard mask layer 21 is a curved surface and the upper surface of the floating gate electrode 14 (FG) covered with the hard mask layer 21 is flat.

Further, in a space of the line & space pattern, a trench extending in the first direction is formed inside the semiconductor substrate 11.

Then, the element isolation insulating layer 12 filling the trench of the semiconductor substrate 11 is formed. Also, the element isolation insulating layer 12 is etched back to cause the element isolation insulating layer 12 to remain only in the trench inside the space of the line & space pattern.

The upper surface of the element isolation insulating layer 12 needs to be higher than the upper surface of the semiconductor substrate 11 or higher than the lower surface of the floating gate electrode 14 (FG). This is intended to prevent the semiconductor substrate 11 from being etched in a slimming process of the floating gate electrode 14 (FG) described later.

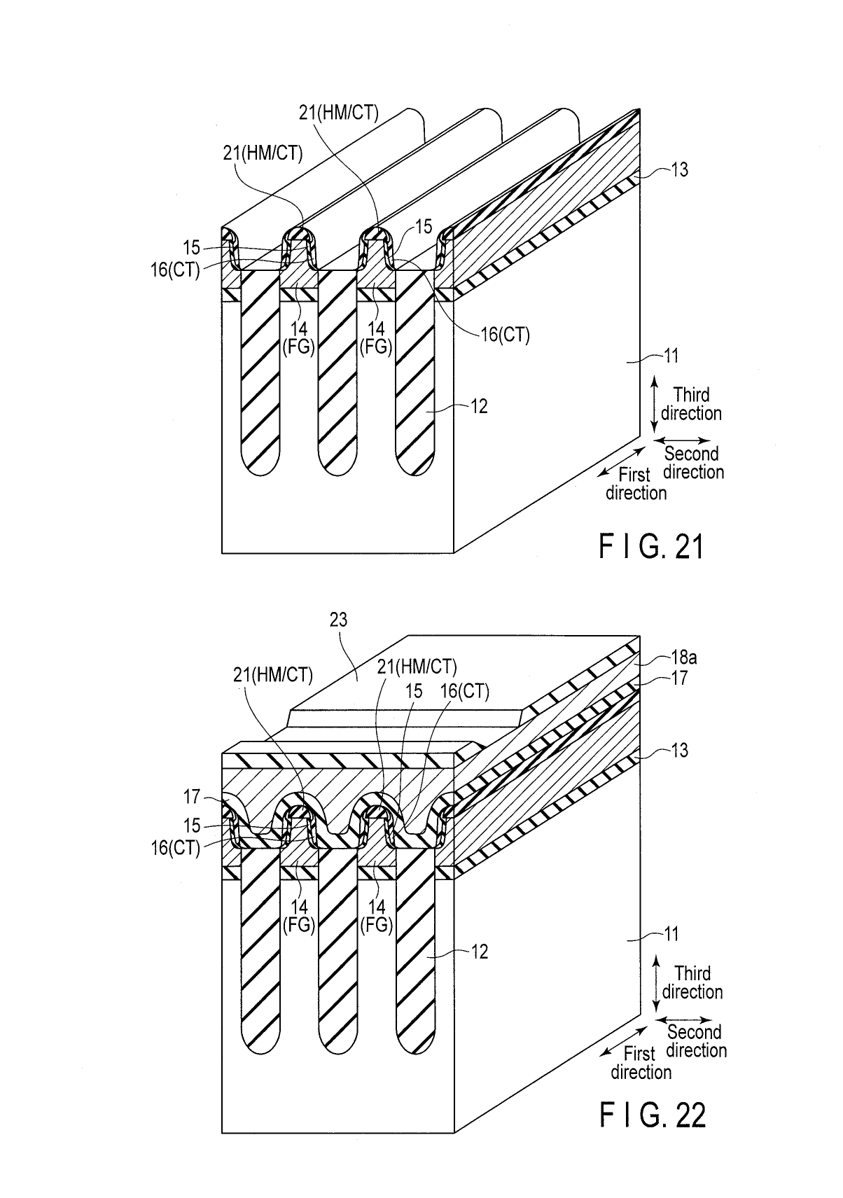

Next, as shown in FIG. 21, the width of the floating gate electrode 14 (FG) is made narrower than that of an active layer AA in the second direction by slimming the floating gate electrode 14 (FG).

If the upper surface of the element isolation insulating layer 12 is as high as or lower than the lower surface of the floating gate electrode 14 (FG), the width of the floating gate electrode 14 (FG) in the second direction becomes a continuously changing width or a constant width.

If, as shown in FIG. 21, the upper surface of the element isolation insulating layer 12 is higher than the lower surface of the floating gate electrode 14 (FG), by contrast, the width of the floating gate electrode 14 (FG) in the second direction becomes discontinuous between the lower portion and the higher portion.

When the etching rate of the hard mask layer 21 is lower than that of the floating gate electrode 14 (FG), the hard mask layer 21 has a width wider than that of the upper portion of the floating gate electrode 14 (FG) in the second direction after the slimming process.

That is, the side faces of the floating gate electrode 14 (FG) and the hard mask layer 21 in the second direction have an overhang shape.

Then, the intermediate insulating layer 15 covering the floating gate electrode 14 (FG) is formed and the charge storage layer 16 (CT) adjacent to the intermediate insulating layer 15 is formed. The intermediate insulating layer 15 and the charge storage layer 16 (CT) are caused to remain self-aligningly on the side face (end in the second direction) of the floating gate electrode 14 (FG) and the side face (end in the second direction) of the hard mask layer 21 by etching the intermediate insulating layer 15 and the charge storage layer 16 (CT) by RIE.

That is, the intermediate insulating layer 15 and the charge storage layer 16 (CT) are self-aligningly formed in a hollow (overhang portion) on the side face of the floating gate electrode 14 (FG) by slimming.

Next, as shown in FIG. 22, the inter-electrode insulating layer 17 covering the floating gate electrode 14 (FG) and the charge storage layer 16 (CT) is formed. Subsequently, the conductive layer 18a as a control gate electrode is formed on the inter-electrode insulating layer 17. Also, a resist layer 23 is formed on the conductive layer 18a by PEP.

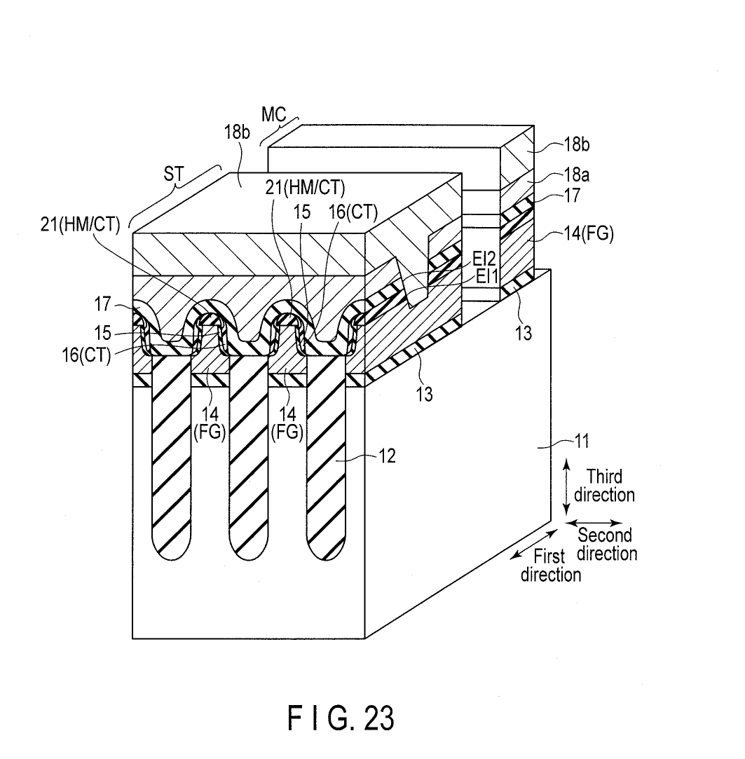

The conductive layer 18a, the inter-electrode insulating layer 17, and the hard mask layer 21 are etched by RIE using the resist layer 23 as a mask. As a result, as shown in FIG. 23, the opening portion EI1 is formed in the hard mask layer 21 and the opening portion EI2 is formed in the inter-electrode insulating layer 17 in an area where the select transistor ST is formed. No opening portion is formed in the inter-electrode insulating layer 17 and the hard mask layer 21 in an area where the memory cell MC is formed. Then, the resist layer 23 is removed.

Next, as shown in FIG. 23, the conductive layer 18b is formed on the conductive layer 18a. Also, a resist layer in a line & space pattern is formed on the conductive layer 18b by PEP. Then, the conductive layers 18a, 18b, the inter-electrode insulating layer 17, the hard mask layer 21, the floating gate electrode 14 (FG), and the gate insulating layer 13 are each etched by RIE using the resist layer as a mask.

As a result, the conductive layers 18a, 18b as control gate electrodes extending in the second direction are formed in an area where the memory cell MC is formed and the conductive layers 18a, 18b as select gate electrodes extending in the second direction are formed in an area where the select transistor ST is formed.

In an area where the select transistor ST is formed, the conductive layers 18a, 18b as select gate electrodes extending in the second direction are in contact with the floating gate electrode 14 (FG) via the opening portion EI1 provided in the hard mask layer 21 and the opening portion EI2 provided in the inter-electrode insulating layer 17.

Then, the space between the memory cell MC and the select transistor ST is filled with an interlayer insulating layer (for example, a silicon oxide layer). However, the space between the memory cell MC and the select transistor ST may be made an air gap.

According to the second embodiment, as described above, the charge storage layers 16 (CT), 16 (FG) can be arranged on the side face of the floating gate electrode 14 (FG) by adopting the convex type floating gate electrode 14 (FG) in the memory cell MC (hybrid cell or double floating cell) to improve the coupling ratio or improve write characteristics by expanding the threshold window.

In the select transistor ST, a structure in which the floating gate electrode 14 (FG) and the conductive layers 18a, 18b as select gate electrodes are short-circuited can be realized by providing the opening portions EI1, EI2 in the hard mask layer 21 and the inter-electrode insulating layer 17 and therefore, reliability of a nonvolatile semiconductor memory device can be improved by preventing a malfunction of the select transistor ST.

A structure similar to the structure of the select transistor ST can be adopted for a peripheral transistor formed around a memory cell array area and an adopted structure will be described together as an example of the peripheral transistor after all the embodiments are described.

### (3) Third Embodiment

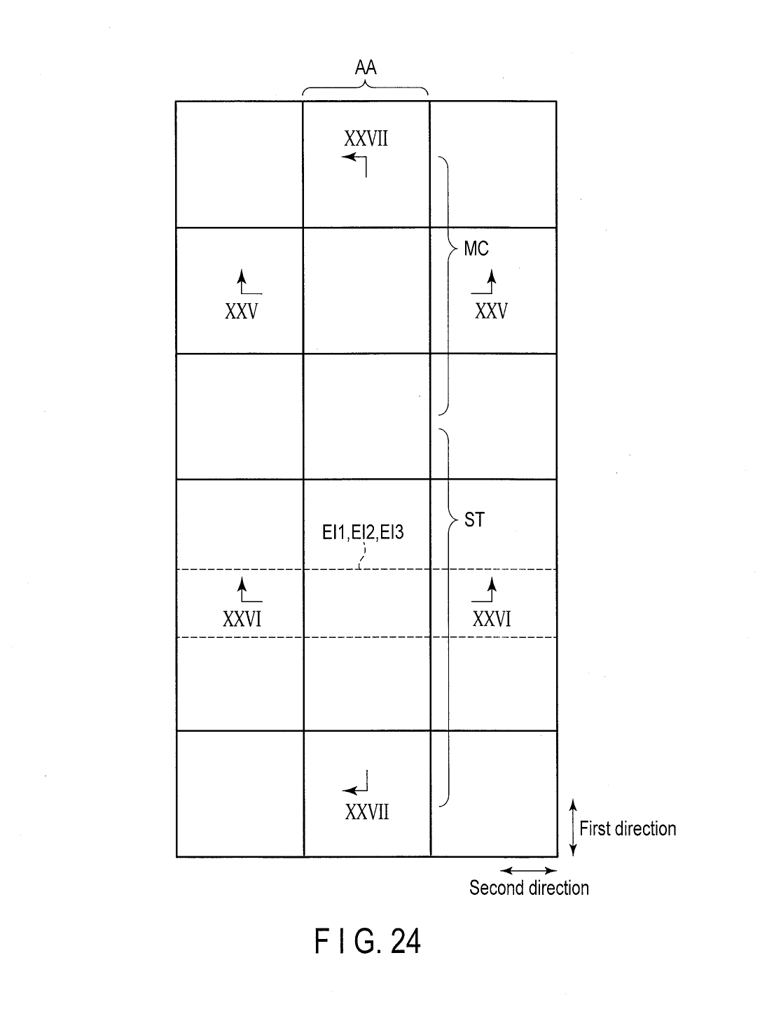

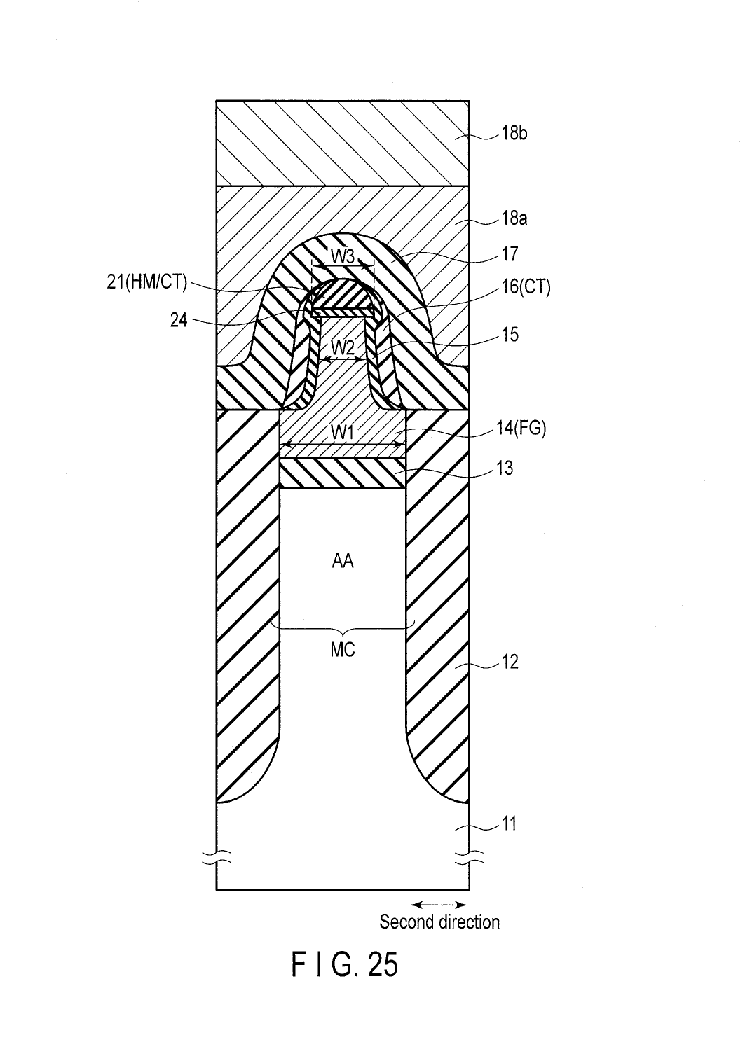

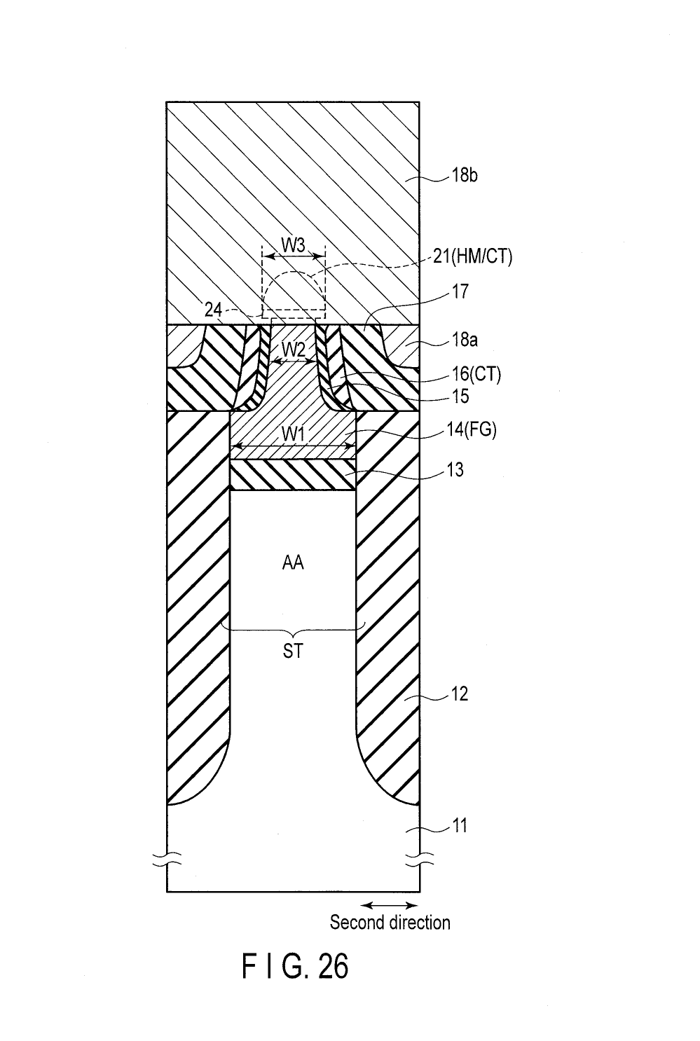

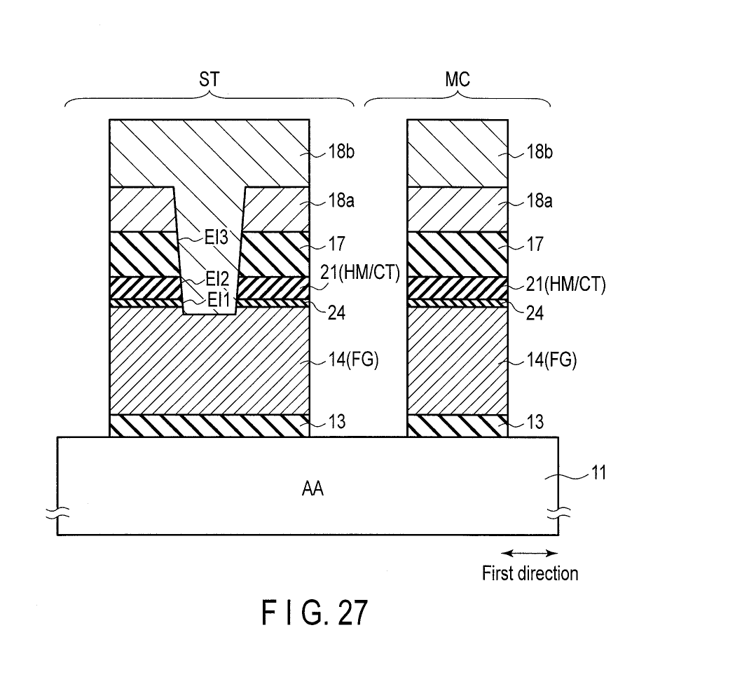

FIG. 24 shows a nonvolatile semiconductor memory device. FIG. 25 is a sectional view along XXV-XXV line in FIG. 24, FIG. 26 is a sectional view along XXVI-XXVI line in FIG. 24, and FIG. 27 is a sectional view along XXVII-XXVII line in FIG. 24.

The third embodiment is a modification of the first embodiment.

Thus, only differences from the first embodiment will be described below and a detailed description thereof is omitted by attaching the same reference numerals to the same elements as those described in the first embodiment.

Features of the structure of a memory cell MC are as described below.

An intermediate insulating layer 24 covers the upper surface of a floating gate electrode 14 (FG). A hard mask layer 21 (HM/CT) is arranged on the intermediate insulating layer 24. The intermediate insulating layer 24 has a third width W3 wider than a second width W2 of a higher portion of the floating gate electrode 14 (FG) in the second direction.

The intermediate insulating layer 24 is an inter-electrode insulating layer and has, for example, a function to block a leak current while writing/erasing.

The hard mask layer 21 (HM/CT) functions as, for example, a charge trap layer. In this case, the hard mask layer 21 (HM/CT) is an insulating layer having a charge trap level. Instead, the hard mask layer 21 (HM/CT) may be caused to function, like the intermediate insulating layer 24, as an inter-electrode insulating layer.

An intermediate insulating layer 15 covers the end (side face) in the second direction of the higher portion of the floating gate electrode 14 (FG) and the end (side face) in the second direction of the intermediate insulating layer 24 and the hard mask layer 21 (HM/CT).

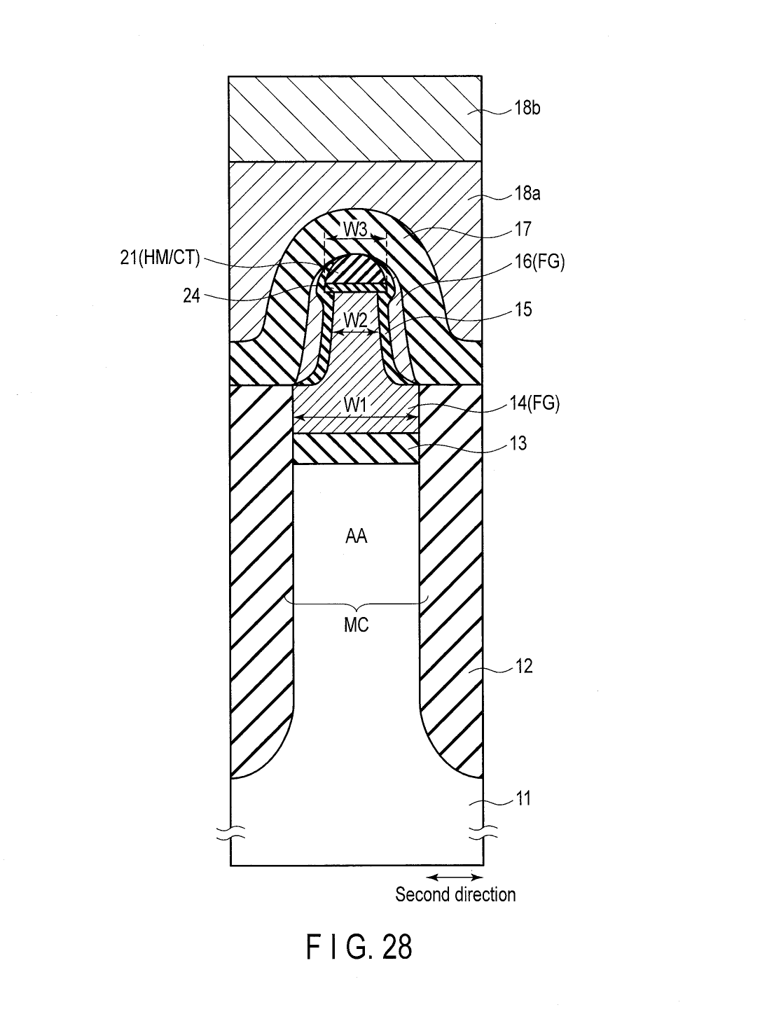

A charge storage layer 16 (CT) is adjacent to the intermediate insulating layer 15. The charge storage layer 16 (CT) is, for example, a charge trap layer (insulating layer having a charge trap level). Instead, however, as shown in FIG. 28, a floating gate electrode (conductive layer in an electrically floating state) may be used as the charge storage layer 16 (FG) (double floating cell).

When the intermediate insulating layer 24 is used as an inter-electrode insulating layer to block a leak current, it is desirable to make the electronic barrier of the intermediate insulating layer 24 higher than that of the intermediate insulating layer 15. This is intended to prevent a leak current in an upper portion (particularly an edge portion) of the floating gate electrode 14 (FG) where electric fields are more likely to be concentrated while writing/erasing.

Materials satisfying conditions for the electronic barrier include alumina for the intermediate insulating layer 24 and silicon nitride for the intermediate insulating layer 15.

When the hard mask layer 21 (HM/CT) and the charge storage layer 16 (CT) are both used as charge trap layers, it is desirable to make the charge trap level of the hard mask layer 21 (HM/CT) lower than that of the charge storage layer 16 (CT). This is intended to particularly improve retention characteristics of the hard mask layer 21 (HM/CT).

For example, the concentration of electric fields in the upper portion (particularly an edge portion) of the floating gate electrode 14 (FG) caused while reading acts in a direction of a dropout of charges trapped in the hard mask layer 21 (HM/CT) therefrom. Such a dropout can be prevented by lowering the charge trap level of the hard mask layer 21 (HM/CT) because charges are thereby trapped by the hard mask layer 21 (HM/CT) more firmly.

Materials satisfying conditions for the charge trap level include alumina and hafnium oxide for the hard mask layer 21 (HM/CT) and silicon nitride for the charge storage layer 16 (CT).

Features of the structure of a select transistor ST are as described below.

The intermediate insulating layer 24 covers the upper surface of the floating gate electrode 14 (FG). The hard mask layer 21 (HM/CT) is arranged on the intermediate insulating layer 24. The intermediate insulating layer 24 has a third width W3 wider than a second width W2 of the higher portion of the floating gate electrode 14 (FG) in the second direction. The intermediate insulating layer 24 also has an opening portion EI1 and the hard mask layer 21 (HM/CT) has an opening portion EI2.

The intermediate insulating layer 15 covers the end (side face) in the second direction of the higher portion of the floating gate electrode 14 (FG) and the end (side face) in the second direction of the intermediate insulating layer 24 and the hard mask layer 21 (HM/CT).

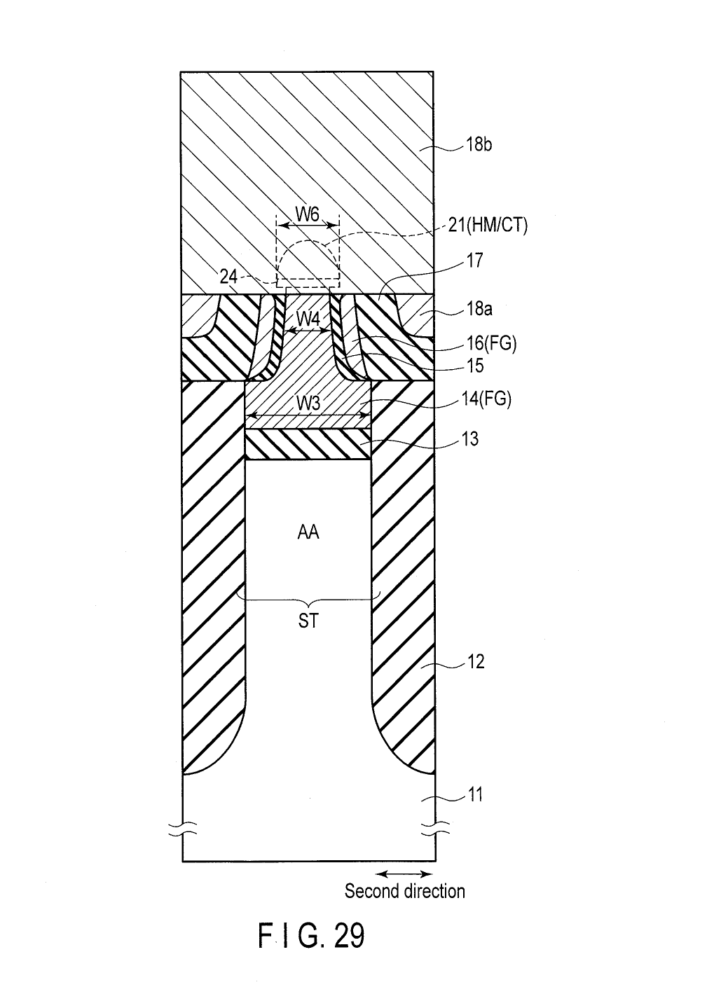

The charge storage layer 16 (CT) is adjacent to the intermediate insulating layer 15. The charge storage layer 16 (CT) is, for example, a charge trap layer (insulating layer). Instead, however, as shown in FIG. 29, a floating gate electrode (conductive layer) may be used as the charge storage layer 16 (FG).

An inter-electrode insulating layer 17 covers the floating gate electrode 14 (FG) and the charge storage layer 16 (CT) and has an opening portion EI3. Conductive layers (select gate electrodes) 18a, 18b are arranged on the inter-electrode insulating layer 17 and extend in the second direction. The conductive layer 18a, 18b are electrically connected to the floating gate electrode 14 (FG) via the opening portion EI1 of the intermediate insulating layer 24, the opening portion EI2 of the hard mask layer 21 (HM/CT), and the opening portion EI3 of the inter-electrode insulating layer 17.

Examples of materials will be described below.

In the structure of FIGS. 24 to 29, the same materials as those described in the first embodiment can be used for a semiconductor substrate 11, an element isolation insulating layer 12, a gate insulating layer 13, the floating gate electrode 14 (FG), the intermediate insulating layer 15, the charge storage layer 16 (CT), the inter-electrode insulating layer 17, and the conductive layers 18a, 18b.

The materials described in the second embodiment can be used for the hard mask layer 21 (HM/CT).

A silicon oxide layer having, for example, a thickness of 10 nm or less can be adopted for, like the intermediate insulating layer 15, the intermediate insulating layer 24. However, the two intermediate insulating layers 15, 24 may be formed from mutually different materials.

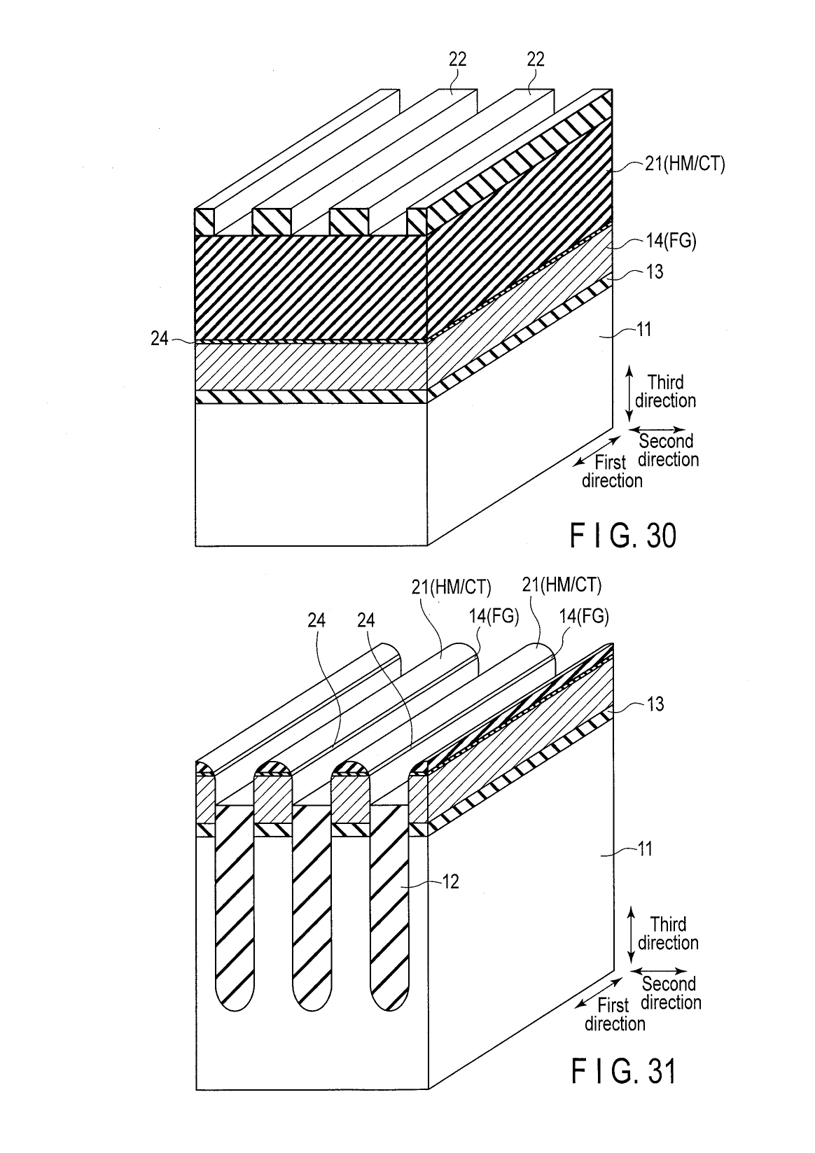

FIGS. 30 to 34 show the method of manufacturing the device in FIGS. 24 to 27.

First, as shown in FIG. 30, the gate insulating layer (tunnel insulating layer) 13 is formed on the semiconductor substrate 11 and the floating gate electrode (conductive layer) 14 (FG) is formed on the gate insulating layer 13. The intermediate insulating layer (for example, a silicon oxide layer) 24 is formed on the floating gate electrode 14 (FG) and the hard mask layer (for example, a silicon nitride layer) 21 is formed on the intermediate insulating layer 24. A resist layer 22 in a line & space pattern is formed on the hard mask 21 by PEP (Photo Engraving Process).

The hard mask layer 21 is etched by RIE using the resist layer 22 as a mask. Then, the resist layer 22 is removed.

Next, the intermediate insulating layer 24, the floating gate electrode 14 (FG), the gate insulating layer 13, and the semiconductor substrate 11 are etched by RIE using the hard mask layer 21 as a mask.

As a result, as shown in FIG. 31, the floating gate electrode 14 (FG) is patterned to a line & space pattern.

The intermediate insulating layer 24 and the hard mask layer 21 remains on the floating gate electrode 14 (FG). The upper surface of the hard mask layer 21 is a curved surface and the upper surface of the floating gate electrode 14 (FG) covered with the hard mask layer 21 and the intermediate insulating layer 24 is flat.

Further, in a space of the line & space pattern, a trench extending in the first direction is formed inside the semiconductor substrate 11.

Then, the element isolation insulating layer 12 filling the trench of the semiconductor substrate 11 is formed. Also, the element isolation insulating layer 12 is etched back to cause the element isolation insulating layer 12 to remain only in the trench inside the space of the line & space pattern.

The upper surface of the element isolation insulating layer 12 needs to be higher than the upper surface of the semiconductor substrate 11 or higher than the lower surface of the floating gate electrode 14 (FG). This is intended to prevent the semiconductor substrate 11 from being etched in a slimming process of the floating gate electrode 14 (FG) described later.

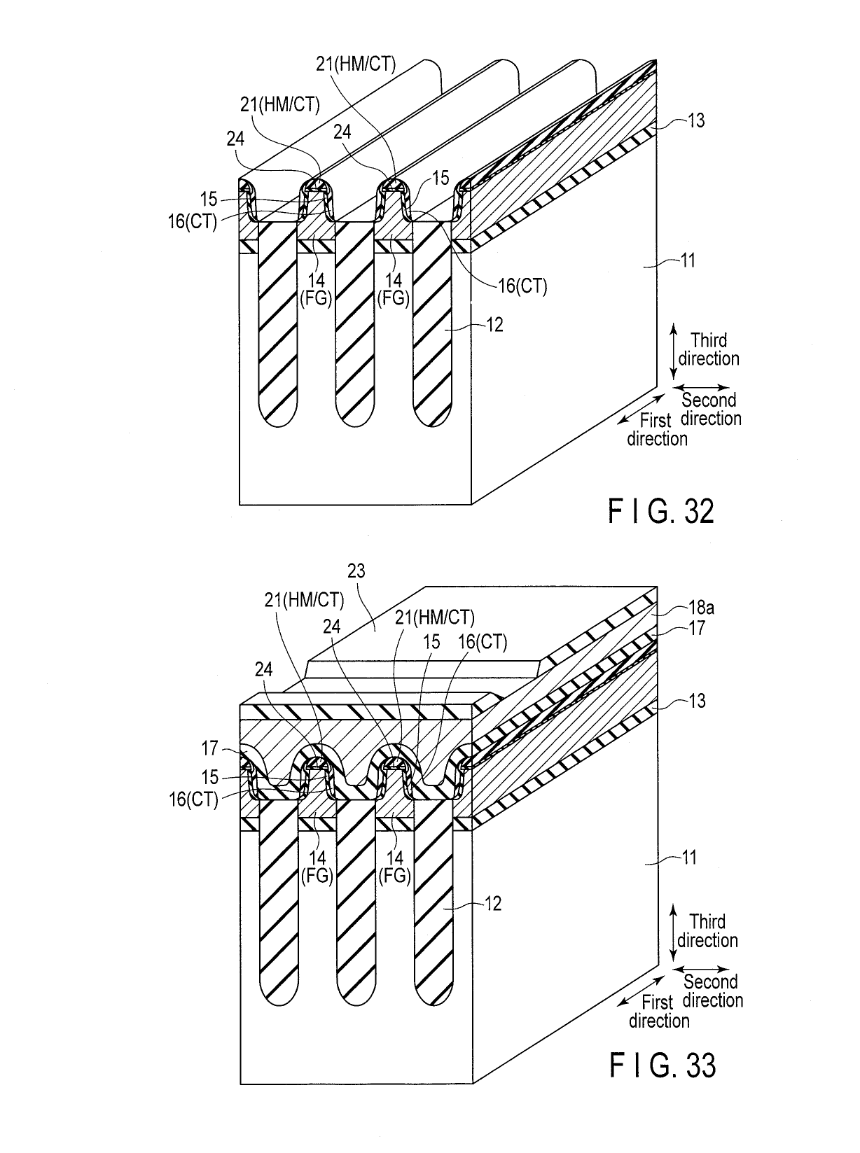

Next, as shown in FIG. 32, the width of the floating gate electrode 14 (FG) is made narrower than that of an active layer AA in the second direction by slimming the floating gate electrode 14 (FG).

If the upper surface of the element isolation insulating layer 12 is as high as or lower than the lower surface of the floating gate electrode 14 (FG), the width of the floating gate electrode 14 (FG) in the second direction becomes a continuously changing width or a constant width.

If, as shown in FIG. 32, the upper surface of the element isolation insulating layer 12 is higher than the lower surface of the floating gate electrode 14 (FG), by contrast, the width of the floating gate electrode 14 (FG) in the second direction becomes discontinuous between the lower portion and the higher portion.

When the etching rate of the hard mask layer 21 and the intermediate insulating layer 24 is lower than that of the floating gate electrode 14 (FG), the hard mask layer 21 and the intermediate insulating layer 24 have a width wider than that of the upper portion of the floating gate electrode 14 (FG) in the second direction after the slimming process.

That is, the side faces of the floating gate electrode 14 (FG), the intermediate insulating layer 24, and the hard mask layer 21 in the second direction have an overhang shape.

Then, the intermediate insulating layer 15 covering the floating gate electrode 14 (FG) is formed and the charge storage layer 16 (CT) adjacent to the intermediate insulating layer 15 is formed. The intermediate insulating layer 15 and the charge storage layer 16 (CT) are caused to remain self-aligningly on the side face (end in the second direction) of the floating gate electrode 14 (FG) and the side face (end in the second direction) of the intermediate insulating layer 24 and the hard mask layer 21 by etching the intermediate insulating layer 15 and the charge storage layer 16 (CT) by RIE.

That is, the intermediate insulating layer 15 and the charge storage layer 16 (CT) are self-aligningly formed in a hollow (overhang portion) on the side face of the floating gate electrode 14 (FG) by slimming.

Next, as shown in FIG. 33, the inter-electrode insulating layer 17 covering the floating gate electrode 14 (FG) and the charge storage layer 16 (CT) is formed. Subsequently, the conductive layer 18a as a control gate electrode is formed on the inter-electrode insulating layer 17. Also, a resist layer 23 is formed on the conductive layer 18a by PEP.

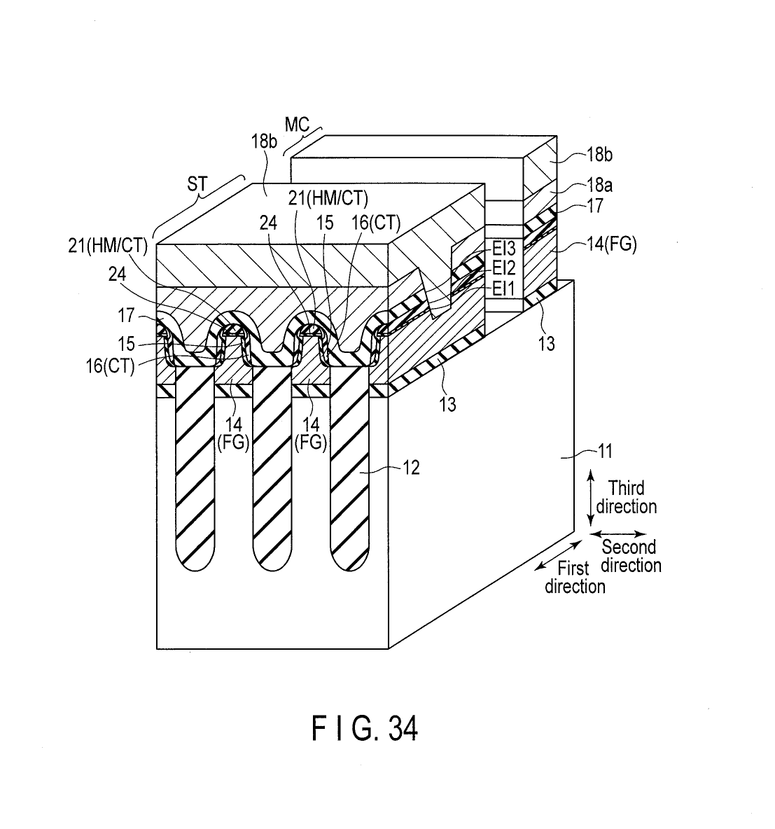

The conductive layer 18a, the inter-electrode insulating layer 17, the hard mask layer 21, and the intermediate insulating layer 24 are etched by RIE using the resist layer 23 as a mask. As a result, as shown in FIG. 34, the opening portion EI1 is formed in the intermediate insulating layer 24, the opening portion EI2 is formed in the hard mask layer 21, and the opening portion EI3 is formed in the inter-electrode insulating layer 17 in an area where the select transistor ST is formed. No opening portion is formed in the inter-electrode insulating layer 17, the hard mask layer 21, and the intermediate insulating layer 24 in an area where the memory cell MC is formed. Then, the resist layer 23 is removed.

Next, as shown in FIG. 34, the conductive layer 18b is formed on the conductive layer 18a. Also, a resist layer in a line & space pattern is formed on the conductive layer 18b by PEP. Then, the conductive layers 18a, 18b, the inter-electrode insulating layer 17, the hard mask layer 21, the intermediate insulating layer 24, the floating gate electrode 14 (FG), and the gate insulating layer 13 are each etched by RIE using the resist layer as a mask.

As a result, the conductive layers 18a, 18b as control gate electrodes extending in the second direction are formed in an area where the memory cell MC is formed and the conductive layers 18a, 18b as select gate electrodes extending in the second direction are formed in an area where the select transistor ST is formed.

In an area where the select transistor ST is formed, the conductive layers 18a, 18b as select gate electrodes extending in the second direction are in contact with the floating gate electrode 14 (FG) via the opening portion EI1 provided in the intermediate insulating layer 24, the opening portion EI2 provided in the hard mask layer 21, and the opening portion EI3 provided in the inter-electrode insulating layer 17.

Then, the space between the memory cell MC and the select transistor ST is filled with an interlayer insulating layer (for example, a silicon oxide layer). However, the space between the memory cell MC and the select transistor ST may be made an air gap.

According to the third embodiment, as described above, the charge storage layers 16 (CT), 16 (FG) can be arranged on the side face of the floating gate electrode 14 (FG) by adopting the convex type floating gate electrode 14 (FG) in the memory cell MC (hybrid cell or double floating cell) to improve the coupling ratio or improve write characteristics by expanding the threshold window.

In the select transistor ST, a structure in which the floating gate electrode 14 (FG) and the conductive layers 18a, 18b as select gate electrodes are short-circuited can be realized by providing the opening portions EI1, EI2, EI3 in the intermediate insulating layer 24, the hard mask layer 21, and the inter-electrode insulating layer 17 and therefore, reliability of a nonvolatile semiconductor memory device can be improved by preventing a malfunction of the select transistor ST.

A structure similar to the structure of the select transistor ST can be adopted for a peripheral transistor formed around a memory cell array area and an adopted structure will be described together as an example of the peripheral transistor after all the embodiments are described.

### (4) Example of Peripheral Transistor

The structure of a peripheral transistor formed around a memory cell array area in the above first to third embodiments will be described.

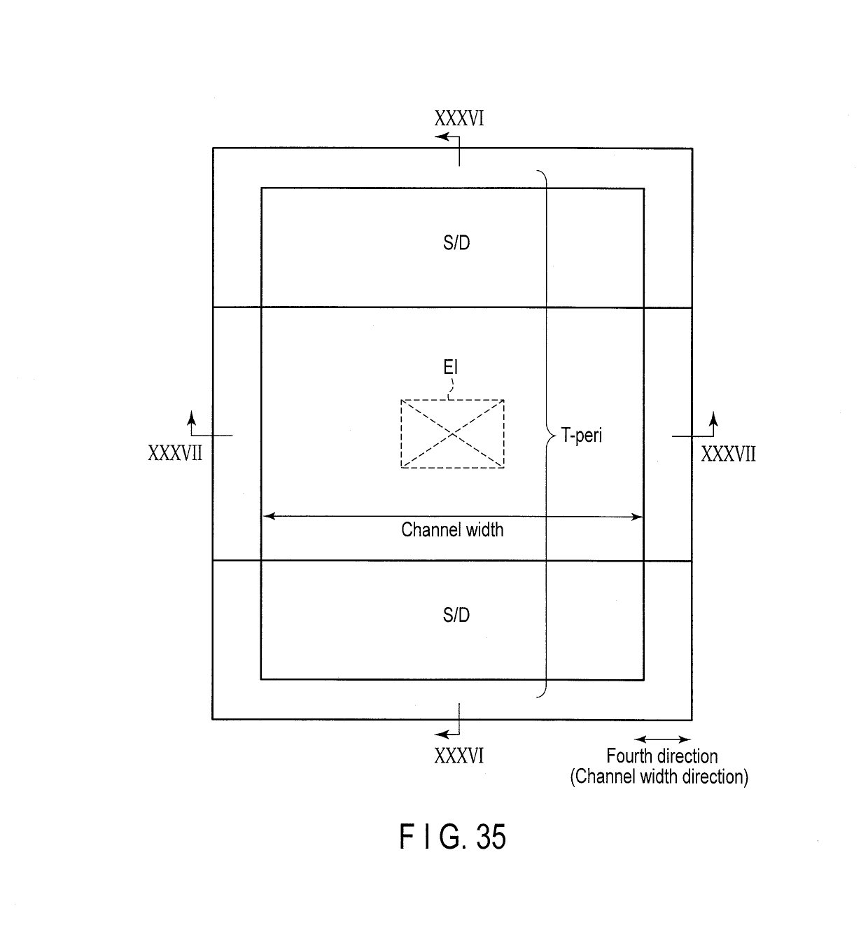

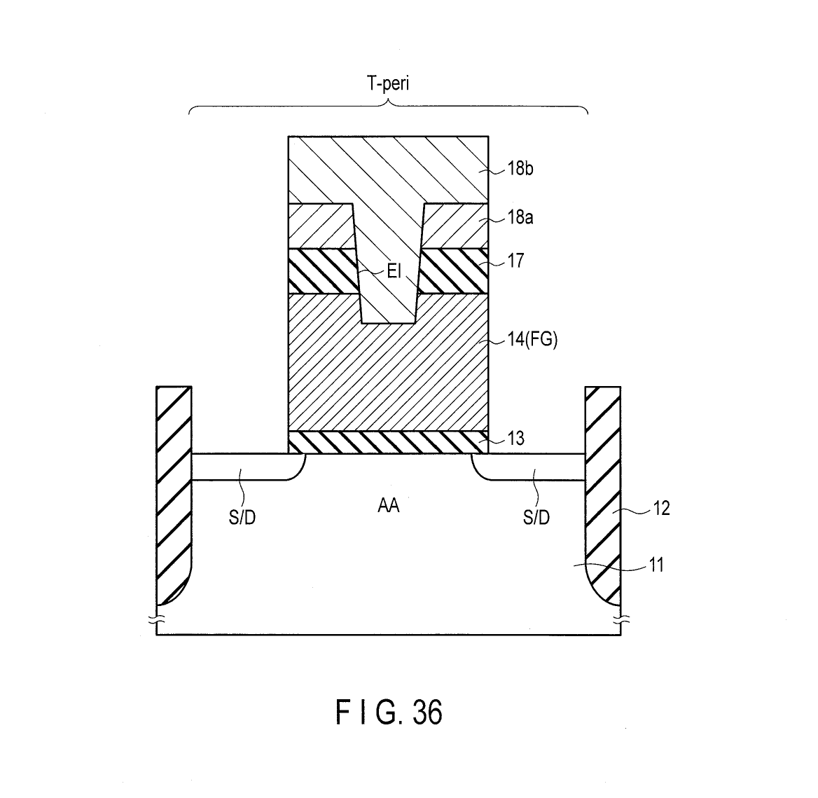

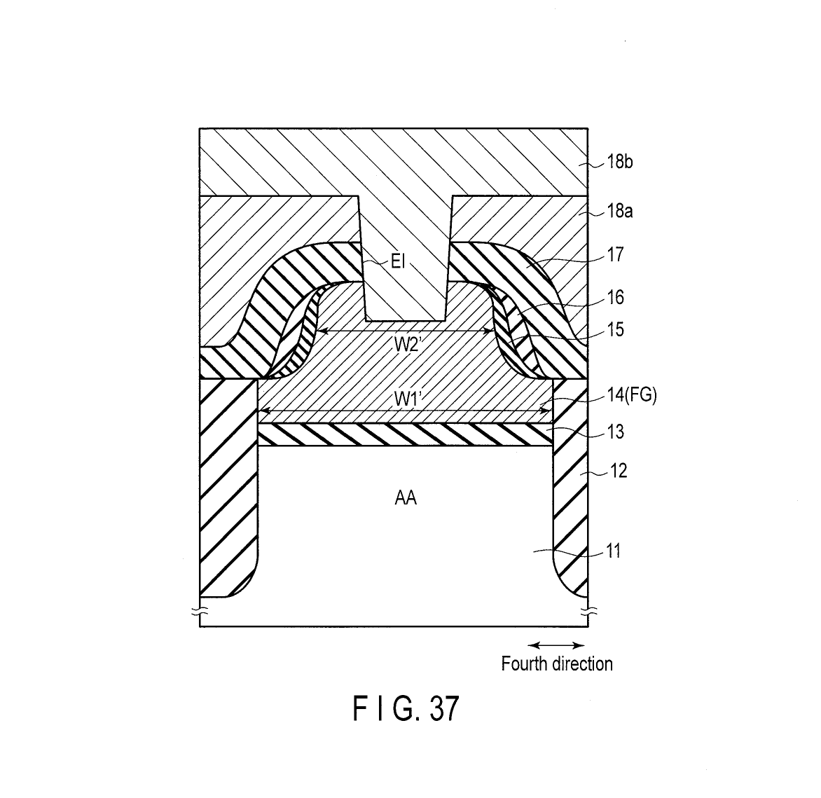

FIG. 35 shows a peripheral transistor. FIG. 36 is a sectional view along XXXVI-XXXVI line in FIG. 35 and FIG. 37 is a sectional view along XXXVII-XXXVII line in FIG. 35. The peripheral transistor shown in these figures corresponds to a memory cell and a select transistor in the first embodiment.

An active area AA as a semiconductor substrate 11 is different from the active area AA described in the first to third embodiments. That is, the active area AA of a peripheral transistor T-peri has a quadrangular shape and is surrounded by an element isolation insulating layer 12. The element isolation insulating layer 12 has an STI structure and is embedded in the semiconductor substrate 11. The element isolation insulating layer 12 has an upper surface higher than the upper surface of the active area.

The structure of the peripheral transistor T-peri is as described below.

A source/drain (impurity area) S/D is arranged inside the active area AA as the semiconductor substrate 11. A gate insulating layer 13 is arranged on the active area AA.

A floating gate electrode 14 (FG) is arranged on the gate insulating layer 13 on a channel area between the source/drain S/D. Like the select transistor ST, the floating gate electrode 14 (FG) is electrically short-circuited to conductive layers 18a, 18b as control gate electrodes.

The floating gate electrode 14 (FG) includes a lower portion having a first width W1′ in a fourth direction parallel to a channel width direction and a higher portion having a second width W2′ narrower than the first width W1′ in the fourth direction.

Also in the peripheral transistor T-peri, for example, the lower portion is a portion of the floating gate electrode 14 (FG) positioned lower than the upper surface of the element isolation insulating layer 12 and the higher portion is a portion of the floating gate electrode 14 (FG) positioned higher than the upper surface of the element isolation insulating layer 12.

The end in the fourth direction of the lower portion of the floating gate electrode 14 (FG) is in contact with the element isolation insulating layer 12.

That is, for example, the first width (channel width) W1′ of the lower portion of the floating gate electrode 14 (FG) is equal to the width of the active area AA in the fourth direction.

The second width W2′ of the higher portion of the floating gate electrode 14 (FG) decreases with an increasing distance (increasing height) from the semiconductor substrate 11. The side face of the floating gate electrode 14 (FG) in the fourth direction is a curved surface.

An intermediate insulating layer 15 covers the end (side face) in the fourth direction of the higher portion of the floating gate electrode 14 (FG).

A charge storage layer 16 (CT) is adjacent to the intermediate insulating layer 15. The charge storage layer 16 (CT) is, for example, a charge trap layer (insulating layer). Instead, however, a floating gate electrode (conductive layer) may be used as the charge storage layer.

An inter-electrode insulating layer 17 covers the floating gate electrode 14 (FG) and the charge storage layer 16 (CT) and has an opening portion EI. The conductive layers (logic gate electrodes) 18a, 18b are arranged on the inter-electrode insulating layer 17 and extend in the fourth direction.

The conductive layer 18a, 18b are electrically connected to the floating gate electrode 14 (FG) via the opening portion EI of the inter-electrode insulating layer 17.

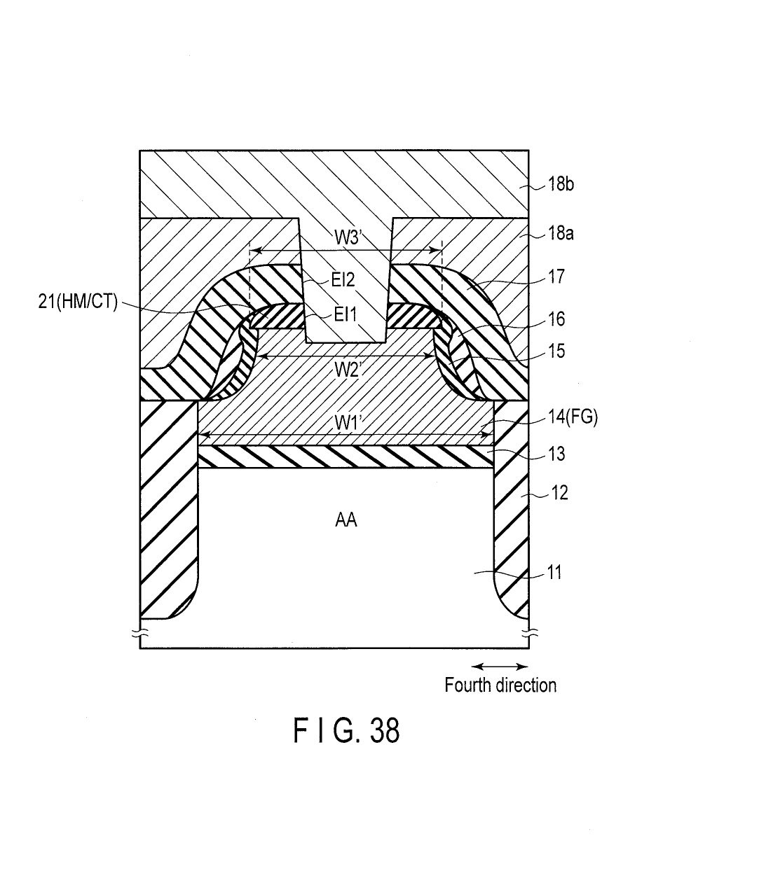

In the case of, as shown in FIG. 38, a peripheral transistor corresponding to a memory cell and a select transistor according to the second embodiment, a hard mask layer 21 (HM/CT) covers the upper surface of a floating gate electrode 14 (FG).

The hard mask layer 21 (HM/CT) has a third width W3′ wider than a second width W2′ of the higher portion of the floating gate electrode 14 (FG) in the fourth direction. The hard mask layer 21 (HM/CT) also includes an opening portion EI1.

An intermediate insulating layer 15 covers the end (side face) in the fourth direction of a higher portion of the floating gate electrode 14 (FG) and the end (side face) in the fourth direction of the hard mask layer 21 (HM/CT).

A charge storage layer 16 (CT) is adjacent to the intermediate insulating layer 15. The charge storage layer 16 (CT) is, for example, a charge trap layer (insulating layer). Instead, however, a floating gate electrode (conductive layer) may be used as the charge storage layer.

An inter-electrode insulating layer 17 covers the floating gate electrode 14 (FG) and the charge storage layer 16 (CT) and has an opening portion EI2. Conductive layers (logic gate electrodes) 18a, 18b are arranged on the inter-electrode insulating layer 17 and extend in the fourth direction.

The conductive layer 18a, 18b are electrically connected to the floating gate electrode 14 (FG) via the opening portion EI1 of the hard mask layer 21 (HM/CT) and the opening portion EI2 of the inter-electrode insulating layer 17.

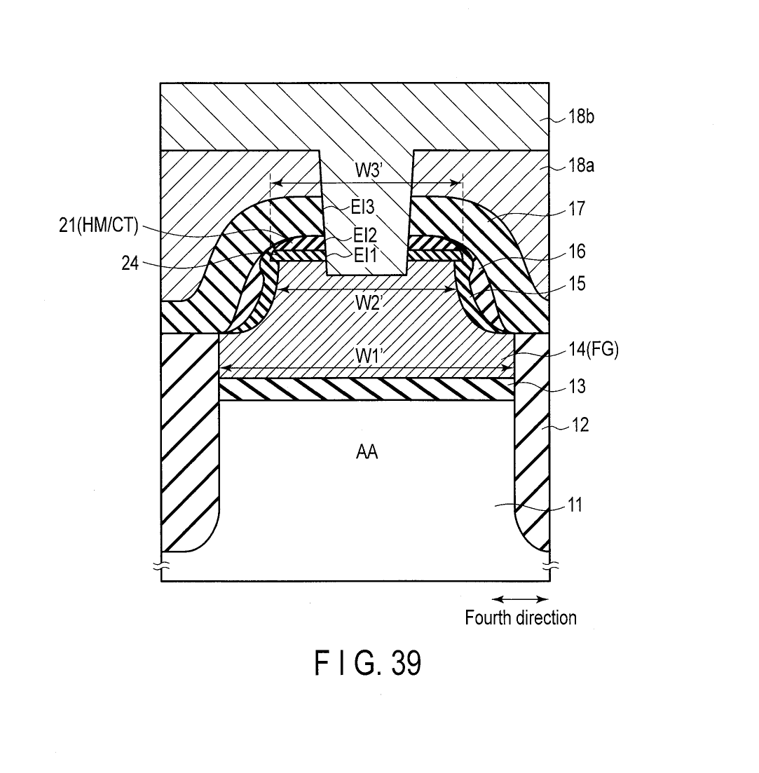

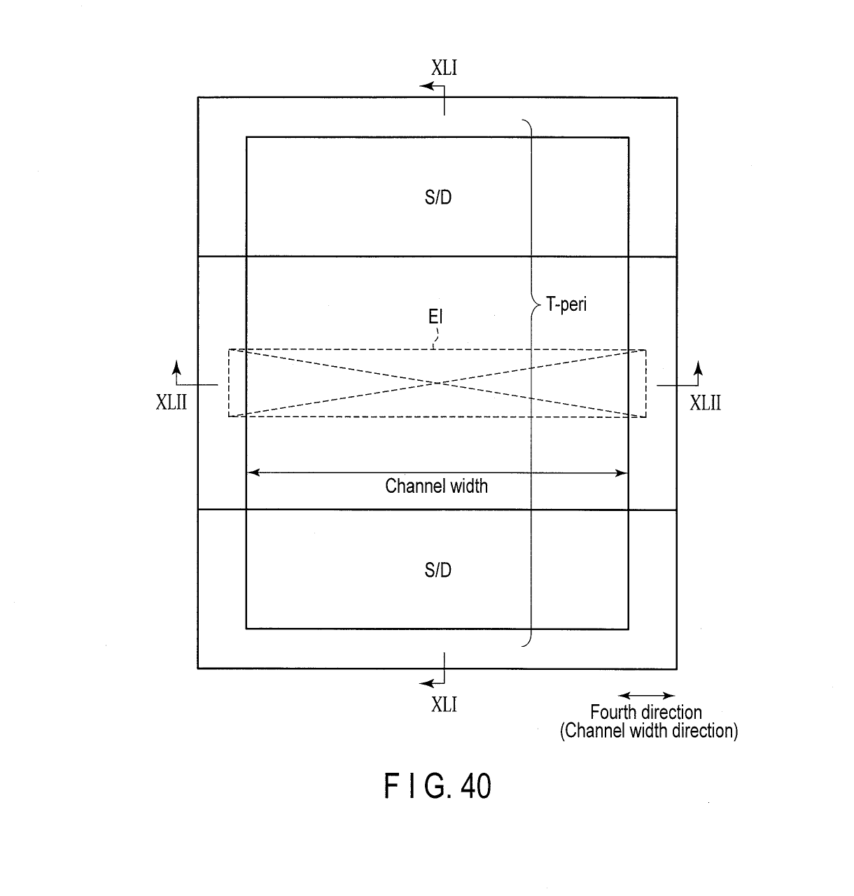

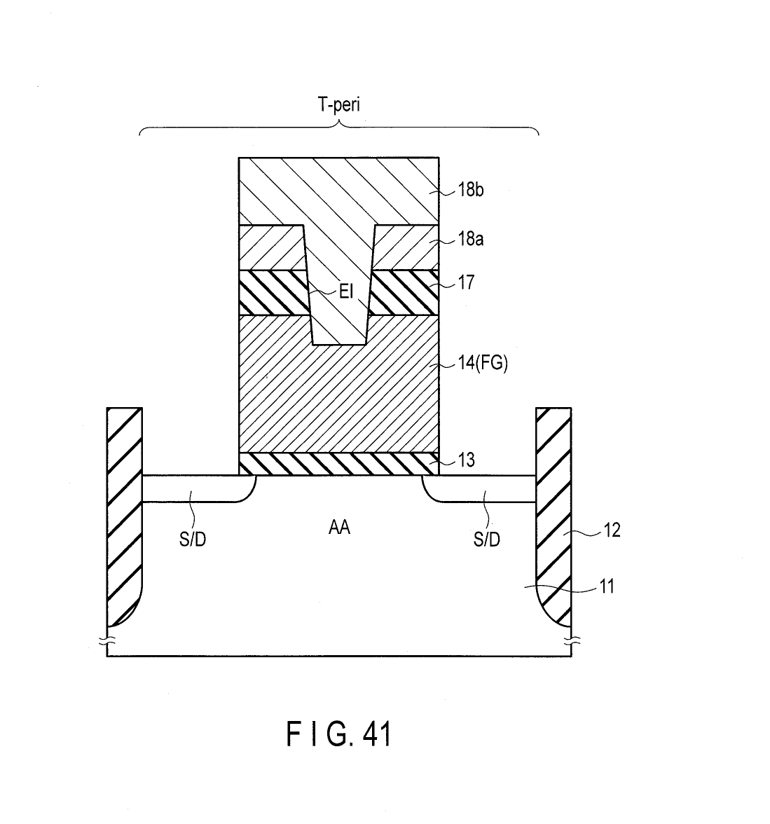

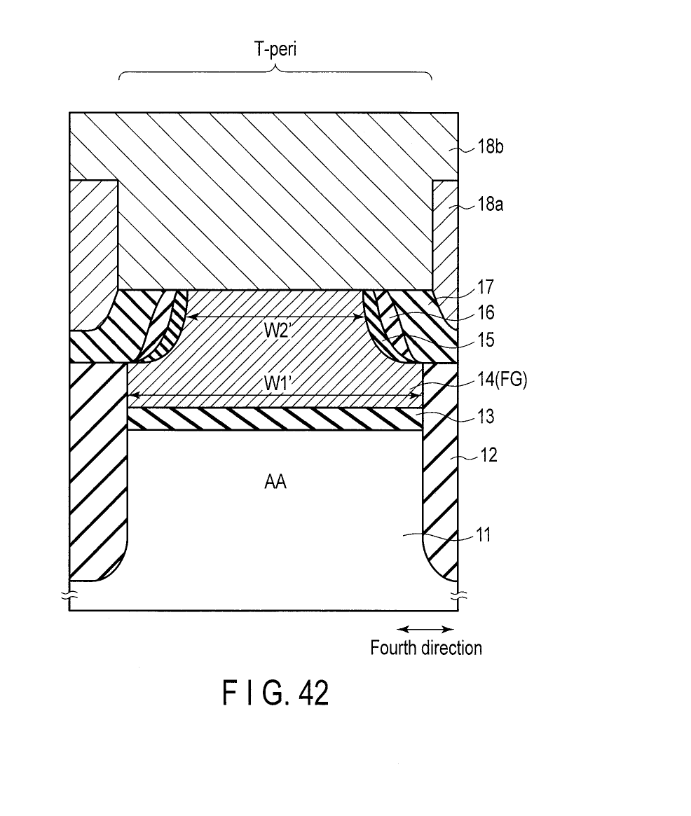

In the case of, as shown in FIG. 39, a peripheral transistor corresponding to a memory cell and a select transistor according to the third embodiment, an intermediate insulating layer 24 covers the upper surface of a floating gate electrode 14 (FG). A hard mask layer 21 (HM/CT) is arranged on the intermediate insulating layer 24.

The intermediate insulating layer 24 has a third width W3′ wider than a second width W2′ of a higher portion of the floating gate electrode 14 (FG) in the fourth direction. The intermediate insulating layer 24 also has an opening portion EI1 and the hard mask layer 21 (HM/CT) has an opening portion EI2.

An intermediate insulating layer 15 covers the end (side face) in the fourth direction of the higher portion of the floating gate electrode 14 (FG) and the end (side face) in the fourth direction of the intermediate insulating layer 24 and the hard mask layer 21 (HM/CT).

A charge storage layer 16 (CT) is adjacent to the intermediate insulating layer 15. The charge storage layer 16 (CT) is, for example, a charge trap layer (insulating layer). Instead, however, a floating gate electrode (conductive layer) may be used as the charge storage layer.

An inter-electrode insulating layer 17 covers the floating gate electrode 14 (FG) and the charge storage layer 16 (CT) and has an opening portion E13. Conductive layers (select gate electrodes) 18a, 18b are arranged on the inter-electrode insulating layer 17 and extend in the fourth direction.

The conductive layer 18a, 18b are electrically connected to the floating gate electrode 14 (FG) via the opening portion EI1 of the intermediate insulating layer 24, the opening portion EI2 of the hard mask layer 21 (HM/CT), and the opening portion EI3 of the inter-electrode insulating layer 17.

In the present example, the conductive layers 18a, 18b as logic gate electrodes of the peripheral transistor T-peri have a two-layer structure, but are not limited to such a structure.

The floating gate electrode 14 (FG) has a first width W1′ (lower portion) and a second width W2′ (higher portion) that are discontinuous, but the floating gate electrode 14 (FG) may have a continuously changing width or a constant width instead.

The above peripheral transistor T-peri can be formed by the same process as the process for forming the select transistor ST described in the first to third embodiments.

### 3. CONCLUSION

According to the embodiments described above, a high-reliability nonvolatile semiconductor memory device eliminating malfunctions of select transistors and peripheral transistors can be realized together with memory cells having a wide threshold window of good write characteristics.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A nonvolatile semiconductor memory device comprising:
a first active area which extends to a first direction, and which has an end in a second direction intersect with the first direction and an upper surface in a third direction intersect with the first and second directions;
an element isolation insulating layer which is adjacent to the end of the first active area, and which has an upper surface higher than the upper surface of the first active area; and
a memory cell on the first active area,
wherein the memory cell comprises:
a first gate insulating layer on the first active area;
a first floating gate electrode on the first gate insulating layer;
a first intermediate insulating layer covering a side face of the first floating gate electrode in the second direction;
a first charge storage layer being faced to the side face of the first floating gate electrode via the first intermediate insulating layer;
a first inter-electrode insulating layer covering the first floating gate electrode and the first charge storage layer; and
a control gate electrode on the first inter-electrode insulating layer, the control gate electrode extending to the second direction.

2. The device of claim 1,
wherein the first floating gate electrode has a lower portion with a first width in the second direction and a higher portion with a second width narrower than the first width in the second direction.

3. The device of claim 1,
wherein the first charge storage layer is a charge trap layer.

4. The device of claim 1,
wherein the first charge storage layer is a floating gate electrode.

5. The device of claim 1, further comprising:
a select transistor on the first active area, the select transistor connected to the memory cell in series,
wherein the select transistor comprises:
a second gate insulating layer on the first active area;
a second floating gate electrode on the second gate insulating layer;
a second intermediate insulating layer covering a side surface of the second floating gate electrode in the second direction;
a second charge storage layer being faced to the side surface of the second floating gate electrode via the second intermediate insulating layer;
a second inter-electrode insulating layer covering the second floating gate electrode and the second charge storage layer, and having an opening portion; and
a select gate electrode being contact with the second floating gate electrode through the opening portion, and extending to the second direction.

6. The device of claim 1, further comprising:
a second active area;
an element isolation insulating layer which surrounds the second active area; and
a peripheral transistor on the second active area,
wherein the peripheral transistor comprises:
a second gate insulating layer on the second active area;
a second floating gate electrode on the second gate insulating layer;
a second intermediate insulating layer covering a side surface of the second floating gate electrode in a fourth direction parallel to a channel width direction;
a second charge storage layer being faced to the side surface of the second floating gate electrode via the second intermediate insulating layer;
a second inter-electrode insulating layer covering the second floating gate electrode and the second charge storage layer, and having an opening portion; and
a logic gate electrode being contact with the second floating gate electrode through the opening portion, and extending to the fourth direction.

7. A nonvolatile semiconductor memory device comprising:
a first active area which extends to a first direction, and which has an end in a second direction intersect with the first direction and an upper surface in a third direction intersect with the first and second directions;
an element isolation insulating layer which is adjacent to the end of the first active area, and which has an upper surface higher than the upper surface of the first active area; and
a memory cell on the first active area,
wherein the memory cell comprises:
a first gate insulating layer on the first active area;
a first floating gate electrode on the first gate insulating layer;
a first hard mask layer covering an upper surface of the first floating gate electrode;
a first intermediate insulating layer covering a side surface of the first floating gate electrode and a side surface of the first hard mask layer in the second direction;
a first charge storage layer being faced to the side surface of the first floating gate electrode via the first intermediate insulating layer;
a first inter-electrode insulating layer covering the first floating gate electrode and the first charge storage layer; and
a control gate electrode on the first inter-electrode insulating layer, the control gate electrode extending to the second direction.

8. The device of claim 7,
wherein the first hard mask layer is alumina, and
the first intermediate insulating layer is silicon nitride.

9. The device of claim 7,
wherein the first floating gate electrode has a lower portion with a first width in the second direction and a higher portion with a second width narrower than the first width in the second direction; and
the first hard mask layer has a third width wider than the second width in the second direction.

10. The device of claim 7,
wherein each of the first charge storage layer and the first hard mask layer is a charge trap layer.

11. The device of claim 7,
wherein the first hard mask layer is one of alumina and hafnium oxide, and
the first charge storage layer is silicon nitride.

12. The device of claim 7,
wherein the first charge storage layer is a floating gate electrode.

13. The device of claim 7, further comprising:
a select transistor on the first active area, the select transistor connected to the memory cell in series,
wherein the select transistor comprises:
a second gate insulating layer on the first active area;
a second floating gate electrode on the second gate insulating layer;
a second hard mask layer covering an upper surface of the second floating gate electrode, and having a first opening portion;
a second intermediate insulating layer covering a side surface of the second floating gate electrode and a side surface of the second hard mask layer in the second direction;
a second charge storage layer being faced to the side surface of the second floating gate electrode via the second intermediate insulating layer;
a second inter-electrode insulating layer covering the second floating gate electrode and the second charge storage layer, and having a second opening portion; and
a select gate electrode being contact with the second floating gate electrode through the first and second opening portions, and extending to the second direction.

14. The device of claim 7, further comprising:
a second active area;
an element isolation insulating layer which surrounds the second active area; and
a peripheral transistor on the second active area,
wherein the peripheral transistor comprises:
a second gate insulating layer on the second active area;
a second floating gate electrode on the second gate insulating layer;
a second hard mask layer covering an upper surface of the second floating gate electrode, and having a first opening portion;
a second intermediate insulating layer covering a side surface of the second floating gate electrode and a side surface of the second hard mask layer in a fourth direction parallel to a channel width direction;
a second charge storage layer being faced to the side surface of the second floating gate electrode via the second intermediate insulating layer;
a second inter-electrode insulating layer covering the second floating gate electrode and the second charge storage layer, and having a second opening portion; and
a logic gate electrode being contact with the second floating gate electrode through the first and second opening portions, and extending to the fourth direction.

15. A nonvolatile semiconductor memory device comprising:
a first active area which extends to a first direction, and which has an end in a second direction intersect with the first direction and an upper surface in a third direction intersect with the first and second directions;
an element isolation insulating layer which is adjacent to the end of the first active area, and which has an upper surface higher than the upper surface of the first active area; and
a memory cell on the first active area,
wherein the memory cell comprises:
a first gate insulating layer on the first active area;
a first floating gate electrode on the first gate insulating layer;
a first intermediate insulating layer covering an upper surface of the first floating gate electrode;
a first hard mask layer on the first intermediate insulating layer;
a second intermediate insulating layer covering a side surface of the first floating gate electrode and side surfaces of the first intermediate insulating layer and the first hard mask layer in the second direction;
a first charge storage layer being faced to the side surface of the first floating gate electrode via the second intermediate insulating layer;
a first inter-electrode insulating layer covering the first floating gate electrode and the first charge storage layer; and
a control gate electrode on the first inter-electrode insulating layer, the control gate electrode extending to the second direction.

16. The device of claim 15,
wherein the first intermediate insulating layer is alumina, and
the second intermediate insulating layer is silicon nitride.

17. The device of claim 15,
wherein the first floating gate electrode has a lower portion with a first width in the second direction and a higher portion with a second width narrower than the first width in the second direction; and
the first intermediate insulating layer has a third width wider than the second width in the second direction.

18. The device of claim 15,
wherein each of the first charge storage layer and the first hard mask layer is a charge trap layer.

19. The device of claim 15,
wherein the first hard mask layer is one of alumina and hafnium oxide, and
the first charge storage layer is silicon nitride.

20. The device of claim 15,
wherein the first charge storage layer is a floating gate electrode.

21. The device of claim 15, further comprising:
a select transistor on the first active area, the select transistor connected to the memory cell in series,
wherein the select transistor comprises:
a second gate insulating layer on the first active area;
a second floating gate electrode on the second gate insulating layer;
a third intermediate insulating layer covering an upper surface of the second floating gate electrode, and having a first opening portion;
a second hard mask layer on the third intermediate insulating layer, the second hard mask layer having a second opening portion;
a fourth intermediate insulating layer covering a side surface of the second floating gate electrode and side surfaces of the third intermediate insulating layer and the second hard mask layer in the second direction;
a second charge storage layer being faced to the side surface of the second floating gate electrode via the fourth intermediate insulating layer;
a second inter-electrode insulating layer covering the second floating gate electrode and the second charge storage layer, and having a third opening portion; and
a select gate electrode being contact with the second floating gate electrode through the first, second and third opening portions, and extending to the second direction.

22. The device of claim 15, further comprising:
a second active;
an element isolation insulating layer which surrounds the second active area; and
a peripheral transistor on the second active area,
wherein the peripheral transistor comprises:
a second gate insulating layer on the second active area;
a second floating gate electrode on the second gate insulating layer;
a third intermediate insulating layer covering an upper surface of the second floating gate electrode, and having a first opening portion;
a second hard mask layer on the third intermediate insulating layer, the second hard mask layer having a second opening portion;
a fourth intermediate insulating layer covering a side surface of the second floating gate electrode and side surfaces of the third intermediate insulating layer and the second hard mask layer in a fourth direction parallel to a channel width direction;
a second charge storage layer being faced to the side surface of the second floating gate electrode via the fourth intermediate layer;
a second inter-electrode insulating layer covering the second floating gate electrode and the second charge storage layer, and having a third opening portion; and
a logic gate electrode being contact with the second floating gate electrode through the first, second and third opening portions, and extending to the fourth direction.
